(19) United States
(12) Patent Application Publication
(10) Pub. No.: US 2023/0389405 A1
(43) Pub. Date: Nov. 30, 2023

(54) METHOD FOR MANUFACTURING LIGHT EMITTING DEVICE

(71) Applicant: Samsung Display Co., Ltd., Yongin-si (KR)

(72) Inventors: HOI-LIM KIM, Yongin-si (KR); SANGHEE YU, Yongin-si (KR); GYUBONG KIM, Yongin-si (KR); SEHUN KIM, Yongin-si (KR); JUYON LEE, Yongin-si (KR); SUN-GYU JUNG, Yongin-si (KR); HYUNG UK CHO, Yongin-si (KR)

(21) Appl. No.: 18/108,627

(22) Filed: Feb. 12, 2023

(30) Foreign Application Priority Data
May 27, 2022 (KR) 10-2022-0065607

(51) Int. Cl. H10K 71/40; H10K 59/35

(52) U.S. Cl. CPC H10K 71/421; H10K 59/353

(57) ABSTRACT

A method for manufacturing a light emitting device includes: providing a base layer and forming an electron transport layer including first and second transport regions. The forming of the electron transport layer includes: applying an electron transport composition including a metal oxide and a photoacid generator such that first and second preliminary transport regions are formed, and irradiating the first and second preliminary transport regions with light, and in the irradiating with the light, the amount of light per unit area irradiated on the first preliminary transport region is different from the amount of light per unit area irradiated on the second preliminary transport region.

This application claims priority to Korean Patent Application No. 10-2022-0065607, filed on May 27, 2022, and all the benefits accruing therefrom under 35 U.S.C. § 119, the contents of which in their entirety are herein incorporated by reference.

### BACKGROUND

The present disclosure herein relates to a method for manufacturing a light emitting device including an electron transport composition.

Various display devices used for multimedia devices such as a television, a mobile phone, a tablet computer, a navigation system, and a game machine are being developed. In such display devices, a so-called self-luminescence light emitting device which realizes display by emitting a light emitting material including an organic compound is used.

In addition, in order to improve the color reproducibility of a display device, the development of a light emitting device using quantum dots as a light emitting material is underway, and the improvement in luminescence efficiency and lifespan of the light emitting device using quantum dots is desirable.

### SUMMARY

The present disclosure provides a method for manufacturing a light emitting device capable of exhibiting improved luminescence efficiency and lifespan properties by applying an electron transport composition including a metal oxide and a photoacid generator to an electron transport layer of the light emitting device. The present disclosure also provides a method for manufacturing a light emitting device with improved reliability by improving the luminescence efficiency of each of light emitting devices emitting light of different colors.

An embodiment of the invention provides a method for manufacturing a light emitting device, the method including: providing a base layer on which first and second pixel regions for emitting first and second color lights different from each other, respectively, are defined, and forming, on the base layer, an electron transport layer including first and second transport regions overlapping the first and second pixel regions, respectively. The forming of an electron transport layer includes: applying an electron transport composition including a metal oxide and a photoacid generator on the first and second pixel regions such first and second preliminary transport regions are formed; and irradiating the first and second preliminary transport regions with light to form the first and second transport regions from the first and second preliminary transport regions, respectively. In the irradiating with the light, the amount of the light per unit area irradiated on the first preliminary transport region is different from the amount of the light per unit area irradiated on the second preliminary transport region.

In an embodiment, the irradiating with the light may include irradiating the first preliminary transport region with a first light and irradiating the second preliminary transport region with a second light. In the irradiating with the first light, a first mask is disposed on the electron transport composition and a first opening overlapping the first preliminary transport region is defined in the first mask. In the irradiating with the second light, a second mask is disposed on the electron transport composition and a second opening overlapping the second preliminary transport region is defined in the second mask.

In an embodiment, an intensity of the first light may be different from an intensity of the second light.

In an embodiment, a period of time during which the first light is irradiated may be different from a period of time during which the second light is irradiated.

In an embodiment, on the base layer, a third pixel region for emitting a third color light different from the first and second color lights may be further defined, in the applying of an electron transport composition, the electron transport composition may be applied on the third pixel region to further form a third preliminary transport region, and the irradiating with the light may further include irradiating the third preliminary transport region with a third light using a third mask in which a third opening overlapping the third preliminary third region is defined such that a third transport region is formed.

In an embodiment, an intensity of the first light, an intensity of the second light, and an intensity of the third light may be different from one another.

In an embodiment, a period of time during which the first light is irradiated, a period of time during which the second light is irradiated, and a period of time during which the third light is irradiated may be different from one another.

In an embodiment, on the base layer, a third pixel region for emitting a third color light different from the first and second color lights may be further defined, in the applying of an electron transport composition, the electron transport composition may be applied on the third pixel region to further form a third preliminary transport region, and in the irradiating of the second preliminary transport region with the second light, a third opening overlapping the third preliminary transport region may be further defined in the second mask, and the third preliminary transport region may be irradiated with the second light.

In an embodiment, in the irradiating with the light, a common mask on which a first opening overlapping the first preliminary transport region and a second opening overlapping the second preliminary transport region are defined may be used, and a transmittance of the light passing through the first opening may be different from a transmittance of the light passing through the second opening.

In an embodiment, a first light control film having a first light transmittance may be disposed in the first opening.

In an embodiment, a second light control film having a second light transmittance different from the first light transmittance may be disposed in the second opening.

In an embodiment, the first opening may be provided in plurality and in a slit form having a first slit width between two adjacent first openings of the plurality of first openings.

In an embodiment, the second opening may be provided in plurality and in a slit form having a second slit width between two adjacent second openings of the plurality of second openings, and the second slit width may be different from the first slit form.

In an embodiment, on the base layer, a third pixel region for emitting a third color light different from the first and second color lights may be further defined, in the applying of an electron transport composition, the electron transport composition may be applied on the third pixel region to further form a third preliminary transport region, and in the irradiating with the light, a third opening overlapping the third preliminary transport region may be further defined in the common mask, and a transmittance of the light passing through the third opening may be different from the transmittance of the light passing through the first opening and the transmittance of the light passing through the second opening.

In an embodiment, on the base layer, a third pixel region for emitting a third color light different from the first and second color lights may be further defined, in the applying of an electron transport composition, the electron transport composition may be applied on the third pixel region to further form a third preliminary transport region, and in the irradiating with the light, a third opening overlapping the third preliminary transport region may be further defined in the common mask, and a transmittance of the light passing through the third opening may be substantially the same as any one of the transmittance of the light passing through the first opening and the transmittance of the light passing through the second opening.

In an embodiment, in the irradiating with light, a first decomposition amount of acid may be decomposed from the photoacid generator in the first preliminary transport region, and a second decomposition amount of acid may be decomposed from the photoacid generator in the second preliminary transport region, and the second decomposition amount may be different from the first decomposition amount.

In an embodiment, the base layer may include first electrodes corresponding to the first and second pixel regions, respectively, and after the forming of the electron transport layer, the method may further include on the electron transport layer, forming a light emitting layer including first and second light emitting layers corresponding to the first and second pixel regions, and forming a second electrode on the light emitting layer, respectively.

In an embodiment, the base layer may include first electrodes corresponding to the first and second pixel regions, respectively, and a light emitting layer disposed on the first electrodes, and including first and second light emitting layers corresponding to the first and second pixel regions, respectively, where the method may further include, after the forming of the electron transport layer, forming a second electrode on the electron transport layer.

In an embodiment, the forming of the electron transport layer may further include, after the applying of the electron transport composition and before the irradiating with the light, performing heat treatment on the first and second preliminary transport regions.

In an embodiment, the forming of the electron transport layer may further include, after the irradiating with the light, performing heat treatment on the first and second transport regions.

In an embodiment, the forming of an electron transport layer may further include, after the irradiating with the light, performing first heat treatment on the first and second transport regions at a first temperature, and after the performing of the first heat treatment, performing second heat treatment on the first and second transport regions at a second temperature different from the first temperature.

In an embodiment of the invention, a method for manufacturing a light emitting device includes: providing a base layer on which first and second pixel regions for emitting first and second color lights different from each other, respectively, are defined, and forming an electron transport layer including first and second transport regions overlapping the first and second pixel regions, respectively, on the base layer. In an embodiment, the forming of an electron transport layer may include applying an electron transport composition including a metal oxide and a photoacid generator on the first and second pixel regions such that first and second preliminary transport regions are respectively formed, and irradiating the first and second preliminary transport regions with light such that the first and second transport regions are formed from the first and second preliminary transport regions, respectively. Mass ratios of the photoacid generator to the metal oxide of the first and second preliminary transport regions may be substantially the same, and in the irradiating with the light, a first decomposition amount of acid may be decomposed from the photoacid generator in the first preliminary transport region, and a second decomposition amount of acid may be decomposed from the photoacid generator in the second preliminary transport region, and the decomposition amount may be different from the first decomposition amount.

### BRIEF DESCRIPTION OF THE FIGURES

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1 is a perspective view of a display device according to an embodiment of the invention;

FIG. 2 is an exploded perspective view of a display device according to an embodiment of the invention;

FIG. 3 is a cross-sectional view of a display module according to an embodiment of the invention taken along line I-I′ of FIG. 1;

FIG. 4 is a plan view of an enlarged portion of a display region of a display module according to an embodiment of the invention;

FIG. 5 is a cross-sectional view of a display module according to an embodiment of the invention taken along line II-II′ of FIG. 4;

FIG. 6 is a cross-sectional view of a display module according to an embodiment of the invention taken along line II-II′ of FIG. 4;

FIG. 7A and FIG. 7B are flowcharts showing a method for manufacturing a light emitting device according to an embodiment of the invention;

FIG. 7C is a flowchart showing a method for manufacturing an electron transport layer according to an embodiment of the invention;

FIG. 8A and FIG. 8B are cross-sectional views showing some of steps of a method for manufacturing a light emitting device according to an embodiment of the invention;

FIG. 8C is a view schematically showing an electron transport composition according to an embodiment of the invention;

FIG. 8D to FIG. 8G are cross-sectional views showing some of steps of a method for manufacturing a light emitting device according to an embodiment of the invention;

FIG. 8H is a view showing steps of a reaction occurring in an electron transport material;

FIG. 8I is a cross-sectional view showing some of steps of a method for manufacturing a light emitting device according to an embodiment of the invention;

FIG. 9A and FIG. 9B are cross-sectional views showing some of steps of a method for manufacturing a light emitting device according to another embodiment of the invention;

FIG. 10A to FIG. 10C are cross-sectional views showing some of steps of a method for manufacturing a light emitting device according to other embodiments of the invention;

FIG. 11A to FIG. 11C are cross-sectional views showing some of steps of a method for manufacturing a light emitting device according to other embodiments of the invention; and

FIG. 12 and FIG. 13 are flowcharts showing a method for manufacturing a light emitting device according to other embodiments of the invention.

### DETAILED DESCRIPTION

In the present disclosure, when an element (or a region, a layer, a portion, and the like) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or,” includes all combinations of one or more of which associated components may define. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention. The terms of a singular form may include the terms of a plural form unless the context clearly indicates otherwise.

In addition, terms such as “below,” “lower,” “above,” “upper,” and the like are used to describe the relationship of the components shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

“About,” “substantially the same” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially the same” can mean within one or more standard deviations, or within ±30%, 20%, 10% or 5% of the stated value. Hereinafter, embodiments of the invention will be described with reference to the accompanying drawings.

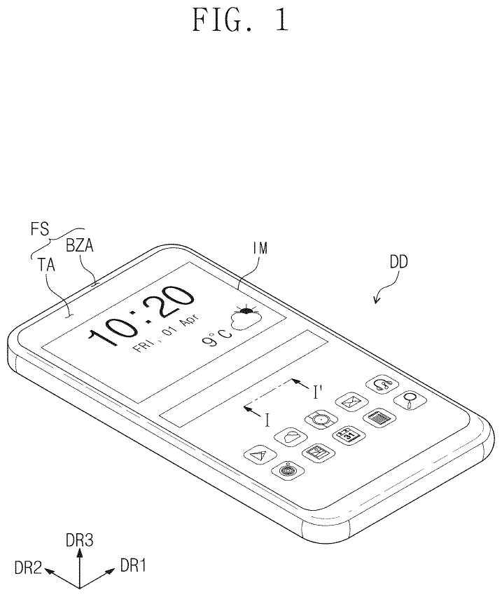

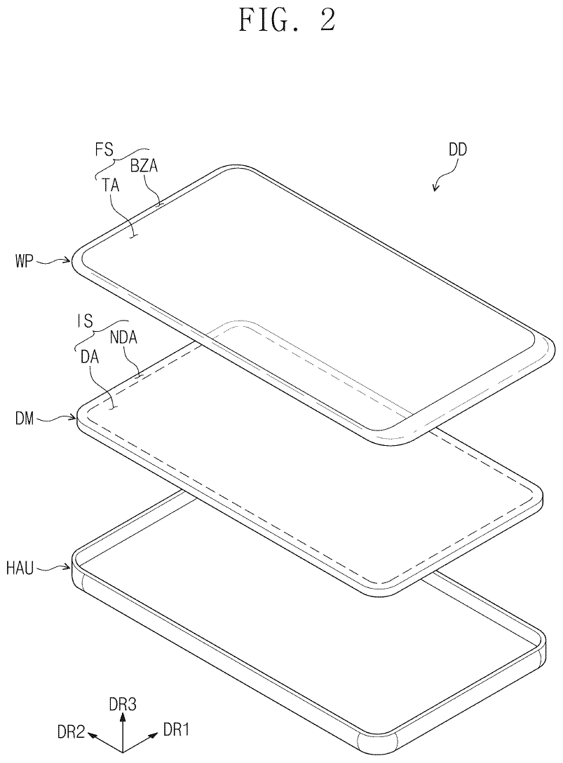

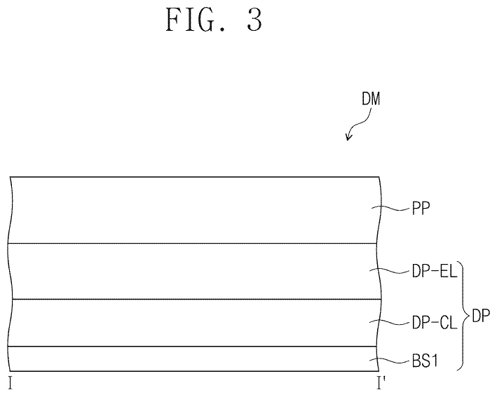

FIG. 1 is a perspective view of a display device according to an embodiment of the invention. FIG. 2 is an exploded perspective view of a display device according to an embodiment of the invention. FIG. 3 is a cross-sectional view of a display module according to an embodiment of the invention taken along line I-I′ of FIG. 1.

In an embodiment, a display device DD may be a large electronic device such as a television, a monitor, or an external advertisement board. Also, the display device DD may be a small and medium-sized electronic device such as a personal computer, a laptop computer, a personal digital terminal, a car navigation system unit, a game console, a smart phone, a tablet, or a camera. However, these are merely exemplary embodiments, and a different display device may be employed as long as it does not depart from the invention. In the present embodiment, the display device DD is exemplarily illustrated as a smart phone.

Referring to FIG. 1 to FIG. 3, the display device DD may display an image IM toward a third direction DR3 on a display surface FS parallel to each of a first direction DR1 and a second direction DR2. The image IM may include both a moving image and a still image. In FIG. 1, as an example of the image IM, a watch window and icons are illustrated. The display surface FS on which the image IM is displayed may correspond to a front surface of the display device DD.

In the present embodiment, a front surface (or an upper surface) and a rear surface (or a lower surface) of each member are defined on the basis of a direction in which the image IM is displayed. The front surface and the rear surface oppose each other in the third direction DR3 and the normal direction of each of the front surface and the rear surface may be parallel to the third direction DR3. Directions indicated by the first to third directions DR1, DR2, and DR3 are a relative concept, and may be converted to different directions. In the present disclosure, “on a plane” or “in a plan view” may mean when viewed in the third direction DR3 (i.e., thickness direction of the light emitting device or the base layer).

As illustrated in FIG. 2, the display device DD according to the present embodiment may include a window WP, a display module DM, and a housing HAU. The window WP and the housing HAU may be coupled to each other to configure the appearance of the display device DD.

The window WP may include an optically transparent insulation material. For example, the window WP may include glass or plastic. The front surface of the window WP may define the display surface FS of the display device DD. The display surface FS may include a transmissive region TA and a bezel region BZA. The transmissive region TA may be an optically transparent region. For example, the transmissive region TA may be a region having a visible light transmittance of about 90% or higher.

The bezel region BZA may be a region having a relatively low light transmittance compared to the transmissive region TA. The bezel region BZA may define the shape of the transmissive region TA. The bezel region BZA is adjacent to the transmissive region TA, and may surround the transmissive region TA. This is only exemplarily illustrated, and in the window WP according to an embodiment of the invention, the bezel region BZA may be omitted. The window WP may include at least one functional layer among a fingerprint prevention layer, a hard coating layer, and a reflection prevention layer, and is not limited to any one embodiment.

The display module DM may be disposed in a lower portion of the window WP. The display module DM may be a component which substantially generates the image IM. The image IM generated in the display module DM is displayed on the display surface IS of the display module DM, and is visually recognized by a user from the outside through the transmissive region TA.

The display module DM includes a display region DA and a non-display region NDA. The display region DA may be a region activated by an electrical signal. The non-display region NDA is adjacent to the display region DA. The non-display region NDA may surround the display region DA. The non-display region NDA is a region covered by the bezel region BZA, and may not be visually recognized from the outside.

As illustrated in FIG. 3, the display module DM may include a display panel DP and an optical member PP.

In the display module DM of an embodiment, the display panel DP may be a light emitting type display. For example, the display panel DP may be a quantum dot light emitting display panel including a quantum dot light emitting device. However, the embodiment of the invention is not limited thereto, and the display panel DP may be an organic light emitting display panel including an organic electroluminescence device.

The display panel DP may include a first base substrate BS1, a circuit layer DP-CL, and a display device layer DP-EL.

The first base substrate BS1 may be a member which provides a base surface on which the circuit layer DP-CL and the display device layer DP-EL are disposed. The first base substrate BS1 may be a glass substrate, a metal substrate, or a plastic substrate. However, the embodiment of the invention is not limited thereto, and the first base substrate BS1 may be an inorganic layer, an organic layer, or a composite material layer. The first base substrate BS1 may be a flexible substrate which may be easily bent or folded.

The circuit layer DP-CL is disposed on the first base substrate BS1, and the circuit layer DP-CL may include a plurality of transistors (not shown). For example, the circuit layer DP-CL may include a switching transistor and a driving transistor for driving a light emitting device of the display device layer DP-EL.

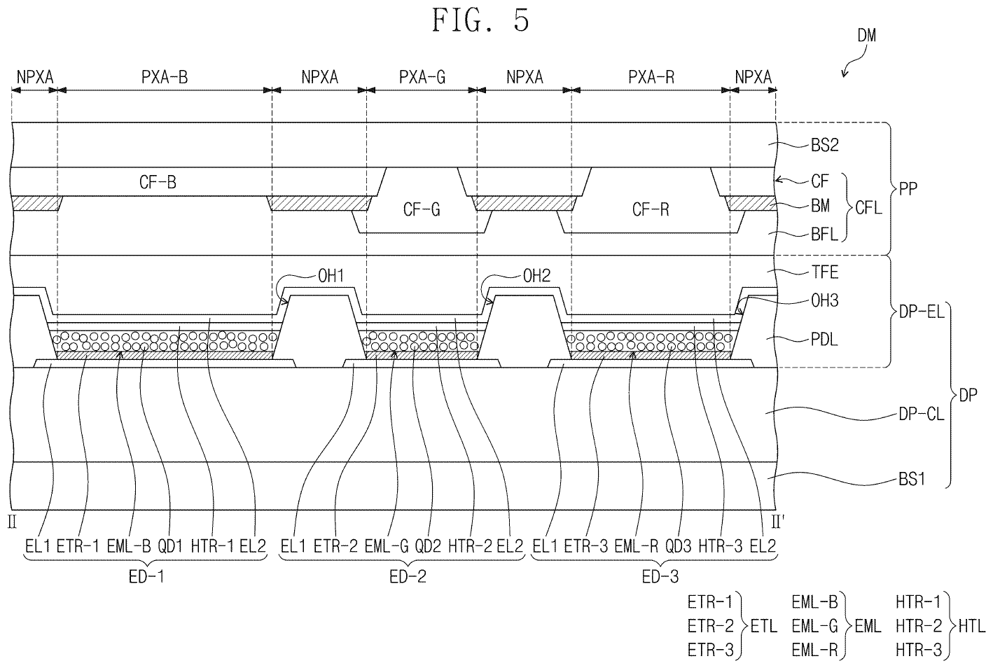

The display device layer DP-EL is disposed on the circuit layer DP-CL, and the display device layer DP-EL may include a plurality of light emitting devices ED-1, ED-2, and ED-3 (see FIG. 5). The display device layer DP-EL will be described in detail later.

The optical member PP may be disposed on the display panel DP to control reflective light in the display panel DP caused by external light. For example, the optical member PP may include a color filter layer or a polarizing layer. However, according to another embodiment of the invention, the optical member PP may be omitted.

The housing HAU may be coupled to the window WP. The housing HAU may be coupled to the window WP and provide a predetermined internal space. The display module DM may be accommodated in the internal space.

The housing HAU may include a material having relatively high rigidity. For example, the housing HAU may include glass, plastic, or a metal, or may include a plurality of frames and/or plates composed of a combination thereof. The housing HAU may stably protect components of the display device DD received in the internal space from an external impact.

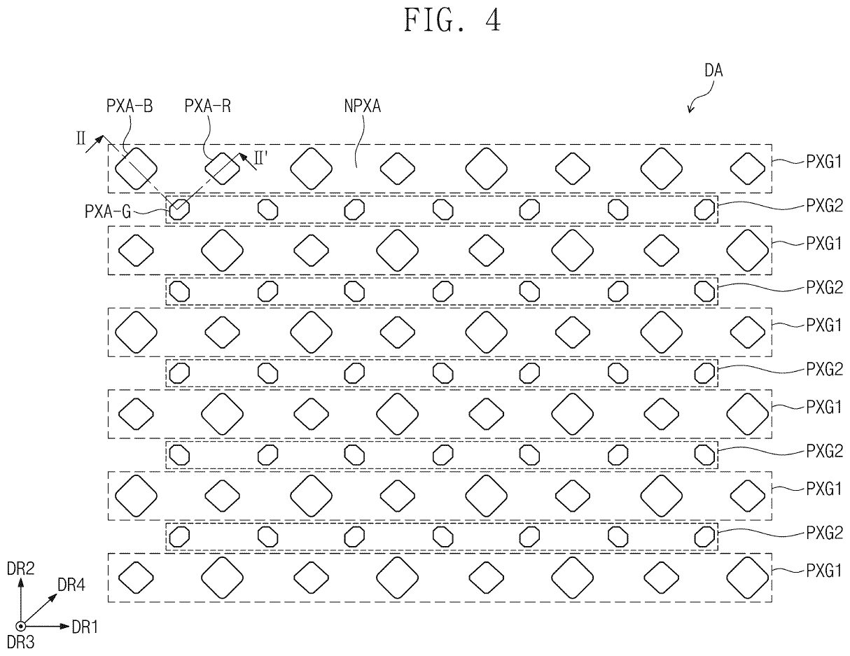

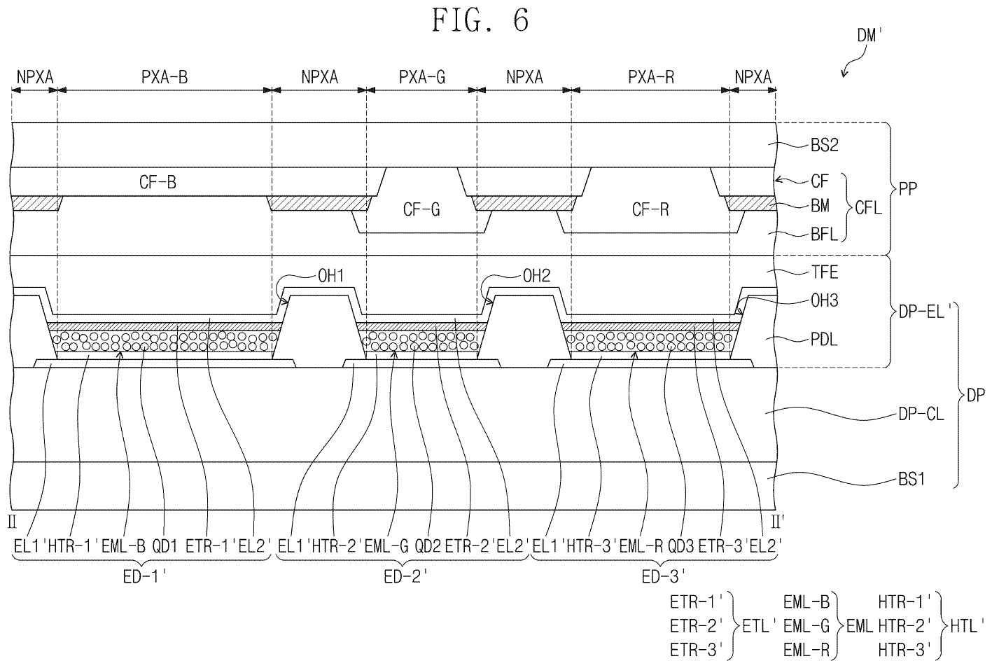

FIG. 4 is a plan view of a part of the configuration of a display module according to an embodiment of the invention. FIG. 5 is a cross-sectional view of a display module according to an embodiment of the invention taken along line II-II′. FIG. 6 is a cross-sectional view of a display module according to an embodiment of the invention taken along line II-II′. FIG. 4 illustrates a plane of the display module DM (see FIG. 2) viewed on the display surface IS (see FIG. 2) of the display module DM (see FIG. 2), which illustrates an enlarged portion of the display region DA of the display module DM (see FIG. 2).

Referring to FIG. 4, the display region DA may include pixel regions PXA-B, PXA-G, and PXA-R and a peripheral region NPXA surrounding the pixel regions PXA-B, PXA-G, and PXA-R.

The pixel regions PXA-B, PXA-G, and PXA-R may correspond to regions from which light provided from light emitting devices ED-1, ED-2, and ED-3 to be described with reference to FIG. 5 is emitted. The pixel regions PXA-B, PXA-G, and PXA-R may include first to third pixel regions PXA-B, PXA-G, and PXA-R. The first to third pixel regions PXA-B, PXA-G, and PXA-R may be distinguished according to the color of light emitted toward the outside of the display module DD (see FIG. 2).

The first to third pixel regions PXA-B, PXA-G, and PXA-R may provide first to third color lights which have different colors from each other, respectively. For example, the first color light may be blue light, the second color light may be green light, and the third color light may be red light. However, examples of the first to third color lights are not limited to the above examples.

The peripheral region NPXA sets boundaries of the first to third pixel regions PXA-B, PXA-G, and PXA-R, and may prevent color mixing between the first to third pixel regions PXA-B, PXA-G, and PXA-R.

Each of the first to third pixel regions PXA-B, PXA-G, and PXA-R is provided in plurality, and may be repeatedly disposed while having a predetermined arrangement form in the display region DA. For example, the first and third pixel regions PXA-B and PXA-R may be alternately arranged along the first direction DR1 and form a first group PXG1. The second pixel regions PXA-G may be arranged along the first direction DR1 and form a second group PXG2. Each of the first group PXG1 and the second group PXG2 may be provided in plurality, and the first groups PXG1 and the second groups PXG2 may be alternately arranged along the second direction DR2.

One second pixel region PXA-G may be disposed spaced apart in a fourth direction DR4 from one first pixel region PXA-B or one third pixel region PXA-R. The fourth direction DR4 may be defined as a direction between the first and second directions DR1 and DR2.

FIG. 4 exemplarily illustrates the arrangement form of the first to third pixel regions PXA-B, PXA-G, and PXA-R and, but the first to third pixel regions PXA-B, PXA-G, and PXA-R may be arranged in various forms without being limited thereto. In an embodiment, the first to third pixel regions PXA-B, PXA-G, and PXA-R may have a PENTILE™ arrangement form as illustrated in FIG. 4. Alternatively, the first to third pixel regions PXA-B, PXA-R, and PXA-G may have a Stripe arrangement form, or a Diamond Pixel™ arrangement form.

The first to third pixel regions PXA-B, PXA-G, and PXA-R and may have various shapes on a plane. For example, the first to third pixel regions PXA-B, PXA-G, and PXA-R may have shapes such as polygons, circles, ovals, or the like. FIG. 4 exemplarily illustrates the first and third pixel regions PXA-B and PXA-R having a quadrangular shape (or a rhombic shape) on a plane, and the second pixel region PXA-G having an octagonal shape.

The first to third pixel regions PXA-B, PXA-G, and PXA-R may have the same shape as each other on a plane, or at least some thereof may have different shapes from each other. FIG. 4 exemplarily illustrates the first and third pixel regions PXA-B and PXA-R having the same shape as each other on a plane, and the second pixel region PXA-G having a shape different from the shape of the first and third pixel regions PXA-B and PXA-R.

At least some of the first to third pixel regions PXA-B, PXA-G, and PXA-R may have different areas on a plane. According to an embodiment, the area of the third pixel region PXA-R emitting red light may be greater than the area of the second pixel region PXA-G emitting green light, and less than the area of the first pixel region PXA-B emitting blue light. However, the relationship between large and small areas of the first to third pixel regions PXA-B, PXA-G, and PXA-R according to the color of emitted light is not limited thereto, and may vary according to the design of the display module DM (see FIG. 2). Also, without being limited thereto, the first to third pixel regions PXA-B, PXA-G, and PXA-R may have the same area on a plane.

The shapes, areas, arrangements, or the like of the first to third pixel regions PXA-B, PXA-G, and PXA-R of the display module DM (see FIG. 2) of the invention may be designed in various ways in accordance with the color of emitted light, or the shape and configuration of the display module DM (see FIG. 2), and are not limited to the embodiment illustrated in FIG. 4.

Referring to FIG. 5, the display module DM according to an embodiment may include the display panel DP and the optical member PP disposed on the display panel DP, and the display panel DP may include the first base substrate BS1, the circuit layer DP-CL, and the display device layer DP-EL.

In the present embodiment, the display device layer DP-EL may include light emitting devices ED-1, ED-2, and ED-3, a pixel definition film PDL, and an encapsulation layer TFE.

The light emitting devices ED-1, ED-2, and ED-3 may include a first light emitting device ED-1, a second light emitting device ED-2, and a third light emitting device ED-3. Each of the first to third light emitting devices ED-1, ED-2, and ED-3 may include a first electrode EL1, an electron transport layer ETL, a light emitting layer EML, a hole transport layer HTL, and a second electrode EL2 sequentially laminated.

The first electrode EL1 may be disposed on the circuit layer DP-CL. The first electrode EL1 is provided in plurality, and the first electrodes EL1 may correspond to the first to third pixel regions PXA-B, PXA-G, and PXA-R, respectively, and be disposed in a pattern of being spaced apart from each other. In the present embodiment, each of the first electrodes EL1 may be a cathode.

The pixel definition film PDL may be disposed on the circuit layer DP-CL. On the pixel definition film PDL, pixel openings OH1, OH2, and OH3 may be defined. Each of the pixel openings OH1, OH2, and OH3 may expose at least a portion of a corresponding first electrode among the first electrodes EL1. The pixel openings OH1, OH2, and OH3 may include a first pixel opening OH1, a second pixel opening OH2, and a third pixel opening OH3.

In the first electrodes EL1, a region exposed from the pixel definition film PDL by the first pixel opening OH1 is defined as the first pixel region PXA-B. In the first electrodes EL1, a region exposed from the pixel definition film PDL by the second pixel opening OH2 is defined as the second pixel region PXA-G. In the first electrodes EL1, a region exposed from the pixel definition film PDL by the third pixel opening OH3 is defined as the third pixel region PXA-R.

The electron transport layer ETL may be disposed on the first electrodes EL1. The electron transport layer ETL may include a first transport region ETR-1 overlapping a first electrode among the first electrodes EL1 which defines the first pixel region PXA-B, a second transport region ETR-2 overlapping a first electrode which defines the second pixel region PXA-G, and a third transport region ETR-3 overlapping a first electrode which defines the third pixel region PXA-R in a plan view.

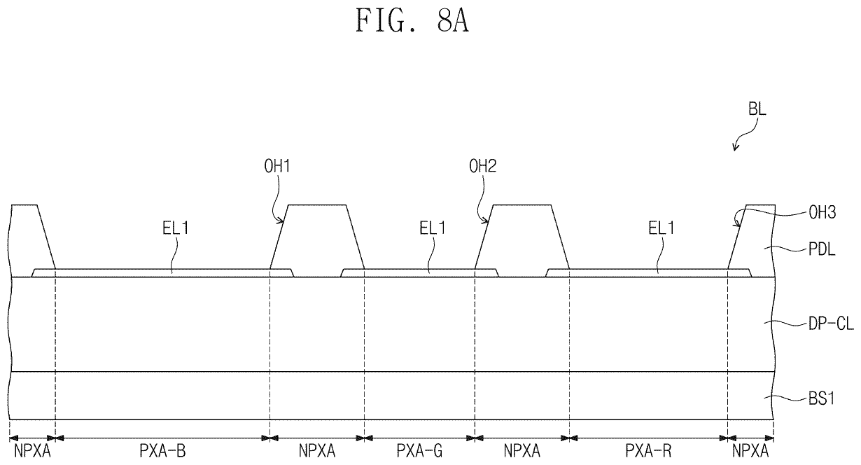

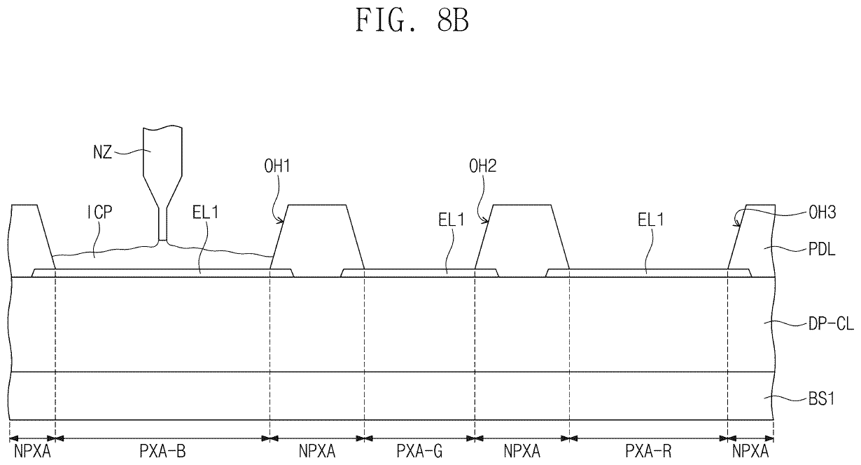

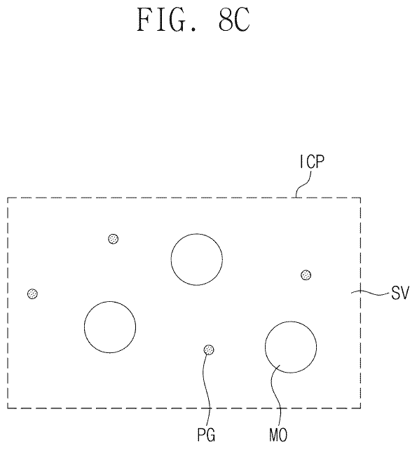

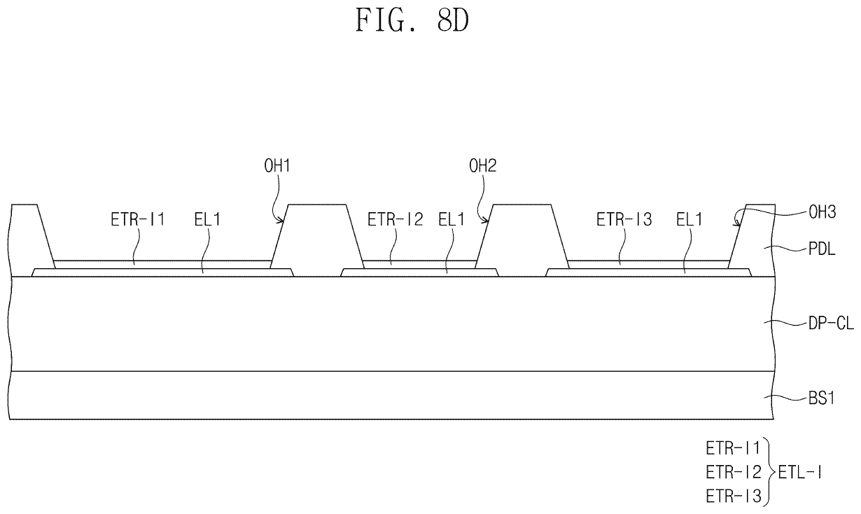

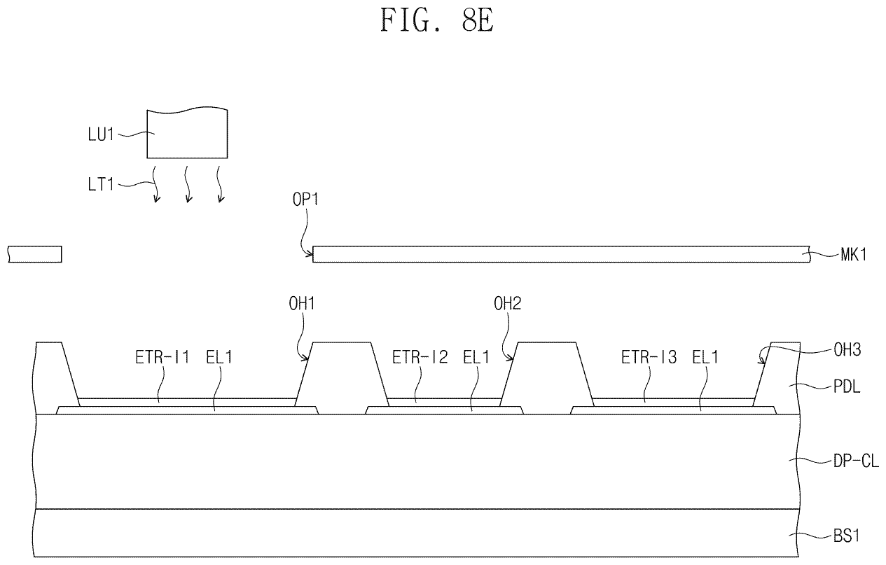

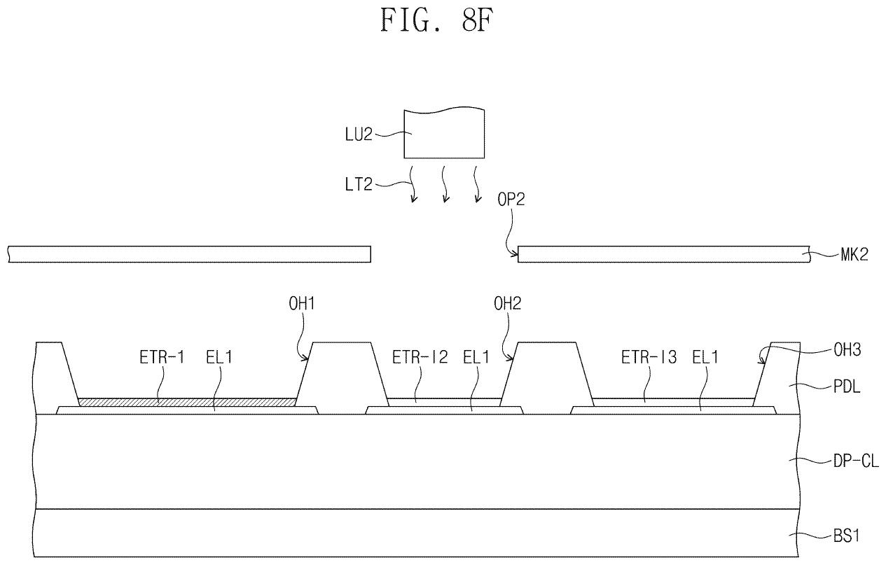

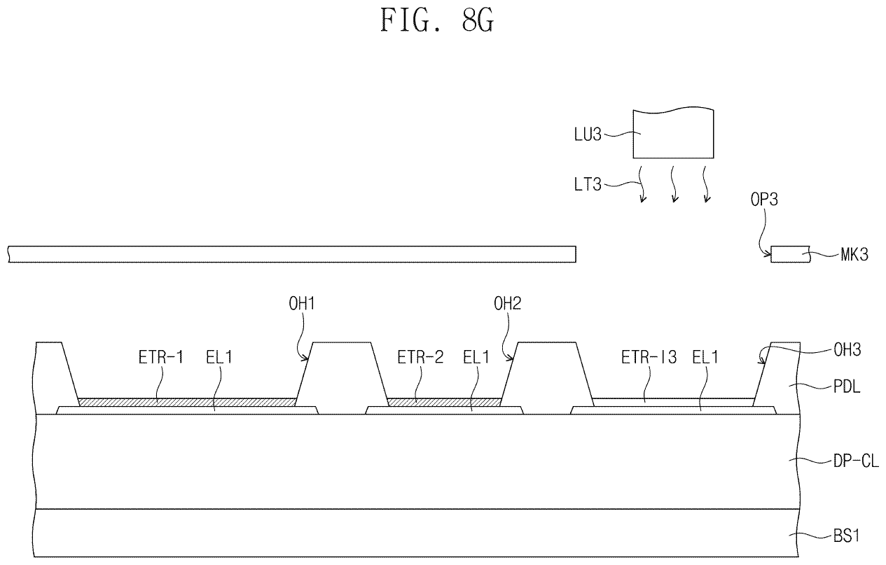

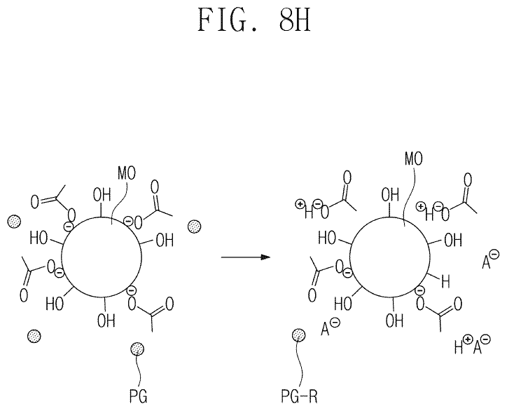

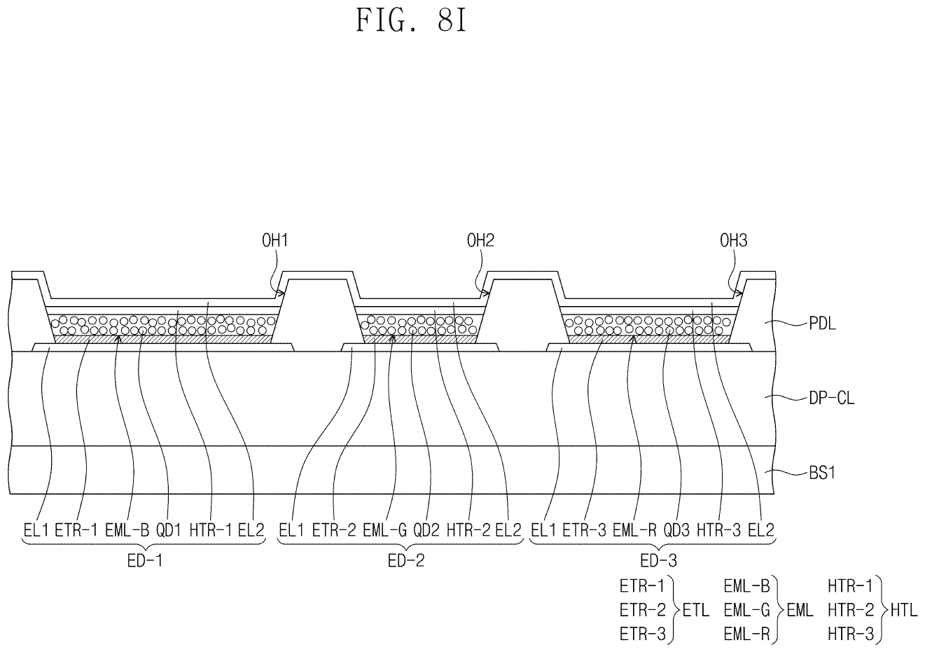

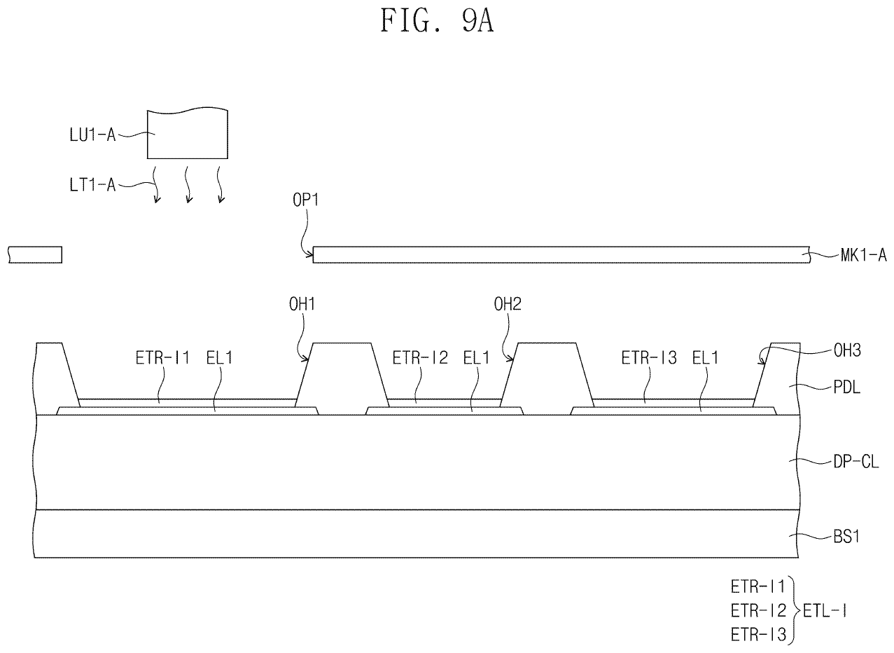

According to the present embodiment, the electron transport layer ETL may include a metal oxide MO (see FIG. 8H), an acid decomposed from a portion of a photoacid generator PG (see FIG. 8H) and a conjugate base of the acid, and a residual photoacid generator PG-R (see FIG. 8H) not decomposed.

By the acid generated from the photoacid generator PG (see FIG. 8H), the metal oxide MO (see FIG. 8H) may be surface-modified, which may lead to an n-doping phenomenon of metal oxide MO (see FIG. 8H) to ultimately lead to an increase in the current density in the light emitting devices ED-1, ED-2, and ED-3. The surface modification of the metal oxide MO (see FIG. 8H) may be described in detail later.

FIG. 5 exemplarily illustrates that the electron transport layer ETL is provided in the form of a plurality of patterns in which the first to third transport regions ETR-1, ETR-2, and ETR-3 are disposed spaced apart from each other, but the embodiment of the invention is not limited thereto, and the electron transport layer ETL is provided as a common layer, and in the common layer, the first to third transport regions ETR-1, ETR-2, and ETR-3 may be divided.

According to another embodiment of the invention, each of the light emitting devices ED-1, ED-2, and ED-3 may further include at least one of an electron injection layer and a hole blocking layer. For example, the electron injection layer may be disposed between the first electrode EL1 and the electron transport layer ETL, and the hole blocking layer may be disposed between the electron transport layer ETL and the light emitting layer EML. The electron injection layer may improve electron injection properties to the electron transport layer ETL without an increase in driving voltage, and the hole blocking layer may prevent hole injection from the hole transport layer HTL to the electron transport layer ETL.

The light emitting layer EML may be disposed on the electron transport layer ETL. The light emitting layer EML may include a first light emitting layer EML-B corresponding to the first pixel region PXA-B, a second light emitting layer EML-G corresponding to the second pixel region PXA-G, and a third light emitting layer EML-R corresponding to the third pixel region PXA-R. The first light emitting layer EML-B may be disposed on the first transport region ETR-1, the second light emitting layer EML-G may be disposed on the second transport region ETR-2, and the third light emitting layer EML-R may be disposed on the third transport region ETR-3.

According to the present embodiment, the first to third light emitting layers EML-B, EML-G, and EML-R may include quantum dots QD1, QD2, and QD3. The quantum dots QD1, QD2, and QD3 may include a first quantum dot QD1, a second quantum dot QD2, and a third quantum dot QD3.

The first light emitting layer EML-B may include the first quantum dot QD1. The first quantum dot QD1 may emit blue light which is the first color light. The second light emitting layer EML-G may include the second quantum dot QD2. The second quantum dot QD2 may emit green light which is the second color light. The third light emitting layer EML-R may include the third quantum dot QD3. The third quantum dot QD3 may emit red light which is the third color light.

In an embodiment, the first color light may be light having a center wavelength in a wavelength region of approximately 410 nanometers (nm) to approximately 480 nm, the second color light may be light having a center wavelength in a wavelength region of approximately 500 nm to approximately 570 nm, and the third color light may be light having a center wavelength in a wavelength region of approximately 625 nm to approximately 675 nm.

The quantum dots QD1, QD2, and QD3 included in a light emitting layer of an embodiment may be semiconductor nanocrystals which may be selected from a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂, CuInGaS₂, and the like.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group III-V compound may further include a Group II metal. For example, InZnP or the like may be selected as the Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

At this time, a binary compound, a ternary compound, or a quaternary compound may be present in a particle at a uniform concentration, or may be present in the same particle with a partially different concentration distribution. In addition, a binary compound, a ternary compound, or a quaternary compound may have a core/shell structure in which one quantum dot surrounds another quantum dot. In the core/shell structure, a binary compound, a ternary compound, or a quaternary compound may have a concentration gradient in which the concentration of an element present in the shell becomes lower toward the center.

In some embodiments, the quantum dots QD1, QD2, and QD3 may have a core-shell structure including a core having the above-described nanocrystals and a shell surrounding the core. The shell of the quantum dots QD1, QD2, and QD3 may serve as a protection layer for preventing the chemical deformation of the core so as to maintain semiconductor properties, and/or a charging layer for imparting electrophoresis properties to a quantum dot. The shell may be a single layer or multiple layers. An example of the shell of the quantum dots QD1, QD2, and QD3 may be a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the like, or a ternary compound such as MgAl₂O₄, CoFe₂O₄, NiFe₂O₄, CoMn₂O₄, or the like. However, the embodiment of the invention is not limited thereto.

Also, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like. However, the embodiment of the invention is not limited thereto.

The quantum dots QD1, QD2, and QD3 may have a full width of half maximum (“FWHM”) of a light emission wavelength spectrum of about 45 nm or less, preferably about 40 nm or less, more preferably about 30 nm or less, and color purity or color reproducibility may be improved in the above range. In addition, light emitted through the quantum dots QD1, QD2, and QD3 is emitted in all directions, so that a wide viewing angle may be improved.

In addition, although the form of the quantum dots QD1, QD2, and QD3 is not particularly limited as long as it is a form commonly used in the art, a quantum dot in the form of, more specifically, nanoparticle, nanotube, nanowire, nanofiber, nano-plate particle, or the like in the shape of a sphere, pyramid, multi-arm, or cubic may be used.

The quantum dots QD1, QD2, and QD3 may control the color of emitted light according to the particle size thereof. Accordingly, the quantum dots QD1, QD2, and QD3 may have various light emission colors such as blue, red, green, and the like.

The smaller the particle size of the quantum dots QD1, QD2, and QD3, light of the shorter wavelength region may be emitted. For example, in the quantum dots QD1, QD2, and QD3 having the same core, the particle size of a quantum dot emitting green light may be smaller than the particle size of a quantum dot emitting red light. In addition, in the quantum dots QD1, QD2, and QD3 having the same core, the particle size of a quantum dot emitting blue light may be smaller than the particle size of a quantum dot emitting green light. However, the embodiment is not limited thereto. Even in the quantum dots QD1, QD2, and QD3 having the same core, the size of a particle may be controlled according to materials for forming a shell and the thickness of the shell.

When the quantum dots QD1, QD2, and QD3 have various light emission colors such as blue, red, green, and the like, the quantum dots QD1, QD2, and QD3 having different light emission colors may have different core materials from each other.

The hole transport layer HTL may be disposed on the light emitting layer EML. The hole transport layer HTL may include a fourth transport region HTR-1 corresponding to the first pixel region PXA-B and disposed on the first light emitting layer EML-B, a fifth transport region HTR-2 corresponding to the second pixel region PXA-G and disposed on the second light emitting layer EML-G, and a sixth transport region HTR-3 corresponding to the third pixel region PXA-R and disposed on the third light emitting layer EML-R.

The hole transport layer HTL may include a common material known in the art. For example, the hole transport layer HTL may further include, for example, a carbazole-based derivative such as N-phenylcarbazole and polyvinylcarbazole, a fluorene-based derivative, a triphenylamine-based derivative such as N,N′-bis(3-methylphenyl)-N,N′-diphenyl-[1,1-biphenyl]-4,4′-diamine (“TPD”) and 4,4′,4″-tris(N-carbazolyl)triphenylamine (“TCTA”), N,N′-di(naphthalene-1-yl)-N,N′-diplienyl-benzidine (“NPD”), 4,4′-Cyclohexylidene bis[N,N-bis(4-methylphenyl)benzenamine] (“TAPC”), 4,4′-Bis[N,N′-(3-tolyl)amino]-3,3′-dimethylbiphenyl (“HMTPD”), (1,3-Bis(N-carbazolyl)benzene (mCP), or the like.

FIG. 5 exemplarily illustrates that the hole transport layer HTL is provided in the form of a plurality of patterns in which the fourth to sixth transport regions HTR-1, HTR-2, and HTR-3 are disposed spaced apart from each other, but the embodiment of the invention is not limited thereto, and the hole transport layer HTL is provided as a common layer, and in the common layer, the fourth to sixth transport regions HTR-1, HTR-2, and HTR-3 may be separated.

According to another embodiment of the invention, each of the light emitting devices ED-1, ED-2, and ED-3 may further include at least one of a hole injection layer and an electron blocking layer. For example, the hole injection layer may be disposed between the second electrode EL2 and the hole transport layer HTL, and the electron blocking layer may be disposed between the hole transport layer HTL and the light emitting layer EML. The hole injection layer may improve hole injection properties to the hole transport layer HTL without an increase in driving voltage, and the electron blocking layer may prevent electron injection from the electron transport layer ETL to the hole transport layer HTL.

The second electrode EL2 may be disposed on the hole transport layer HTL. The second electrode EL2 of the first to third light emitting devices ED-1, ED-2, and ED-3 may be connected to each other and provided in the shape of a single body. That is, the second electrode EL2 may be provided in the form of a common layer. In the present embodiment, the second electrode EL2 may be an anode.

As illustrated in FIG. 5, each of the light emitting devices ED-1, ED-2, and ED-3 of an embodiment may have an inverted device structure in which, based on an upper direction in which light is emitted, the electron transport layer ETL is disposed below the light emitting layer EML, and the hole transport layer HTL is disposed above the light emitting layer EML.

The encapsulation layer TFE may cover the light emitting devices ED-1, ED-2, and ED-3, thereby encapsulating the light emitting devices ED-1, ED-2, and ED-3. The encapsulation layer TFE is disposed on the second electrode EL2, and may be disposed to fill the pixel openings OH1, OH2, and OH3.

The encapsulation layer TFE may have a multi-layered structure in which an inorganic layer/organic layer are repeated. For example, the encapsulation layer TFE may have a structure of an inorganic layer/an organic layer/an inorganic layer. The inorganic layer may protect the light emitting devices ED-1, ED-2, and ED-3 from external moisture, and the organic layer may prevent imprint defects of the light emitting devices ED-1, ED-2, and ED-3 caused by foreign substances introduced during a manufacturing process.

In the present embodiment, the optical member PP may include a second base substrate BS2 and a color filter layer CFL. The display module DM of an embodiment may further include the color filter layer CFL disposed on the light emitting devices ED-1, ED-2, and ED-3 of the display panel DP.

The second base substrate BS2 may be a member which provides a base surface on which the color filter layer CFL or the like are disposed. The second base substrate BS2 may be a glass substrate, a metal substrate, a plastic substrate, or the like. However, the embodiment of the invention is not limited thereto, and the second base substrate BS2 may be an inorganic layer, an organic layer, or a composite material layer.

The color filter layer CFL may include a light blocking part BM and a color filter CF. The color filter CF may include a plurality of color filters CF-B, CF-G, and CF-R. That is, the color filter layer CFL may include a first color filter CF-B which transmits the first color light, a second color filter CF-G which transmits the second color light, and a third color filter CF-R which transmits the third color light.

Each of the color filters CF-B, CF-G, and CF-R may include a polymer photosensitive resin, and a pigment or a dye. The first color filter CF-B may include a blue pigment or a blue dye, the second color filter CF-G may include a green pigment or a green dye, and the third color filter CF-R may include a red pigment or a red dye. The embodiment of the invention is not limited thereto. The first color filter CF-B may not include a pigment or a dye in another embodiment.

The light blocking part BM may be a black matrix. The light blocking part BM may be formed by including an organic light blocking material or an inorganic light blocking material which includes a black pigment or a black dye. The light blocking part BM prevents a light leakage phenomenon, and may separate boundaries between adjacent color filters CF-B, CF-G, and CF-R.

The color filter layer CFL may further include a buffer layer BFL. For example, the buffer layer BFL may be a protective layer for protecting the color filters CF-B, CF-G, and CF-R. The buffer layer BFL may be an inorganic material layer including at least one inorganic material among silicon nitride, silicon oxide, and silicon oxynitride. The buffer layer BFL may be formed of a single layer or a plurality of layers.

In an embodiment illustrated in FIG. 5, it is illustrated that the first color filter CF-B of the color filter layer CFL partially overlaps the second color filter CF-G and the third color filter CF-R, and entirely overlaps the peripheral region NPXA, but the embodiment of the invention is not limited thereto. For example, the first to third color filters CF-B, CF-G, and CF-R may be separated by the light blocking part BM and may not overlap each other. In an embodiment, each the first to third color filters CF-B, CF-G, and CF-R may be disposed corresponding to the first to third pixel regions PXA-B, PXA-G, and PXA-R. According to another embodiment, the color filter layer CFL may be omitted.

FIG. 5 exemplarily illustrates the optical member PP, and according to another embodiment, the optical member PP may include a polarizing layer (not shown). The polarizing layer (not shown) may block external light provided to the display panel DP from the outside. In addition, the polarizing layer (not shown) may reduce reflection light generated in the display panel DP due to external light.

The polarizing layer (not shown) may be a circular polarizer having an anti-reflection function or the polarizing layer (not shown) may include a linear polarizer and a λ/4 phase retarder. The polarizing layer (not shown) may be disposed on the second base substrate BS2 and exposed, or the polarizing layer (not shown) may be disposed in a lower portion of the second base substrate BS2.

Referring to FIG. 6, a display device layer DP-EL′ of a display module DM′ according to an embodiment of the invention includes light emitting devices ED-1′, ED-2′, and ED-3′, and the light emitting devices ED-1′, ED-2′, and ED-3′ may include a first light emitting device ED-1′, a second light emitting device ED-2′, and a third light emitting device ED-3′. The same/similar reference numerals are used for the same/similar components as those described with reference to FIG. 5, and redundant descriptions thereof are omitted.

Each of the first to third light emitting devices ED-1′, ED-2′, and ED-3′ may include a first electrode EL1′, a hole transport layer HTL′, a light emitting layer EML, an electron transport layer ETL′, and a second electrode EL2. According to the present embodiment, the first electrode EL1′ may correspond to an anode, and the second electrode EL2′ may correspond to a cathode.

The hole transport layer HTL′ may be disposed between the first electrode EL1′ and the light emitting layer EML. That is, a fourth transport region HTR-1′ may be disposed on the first electrode EL1′ defining the first pixel region PXA-B, a fifth transport region HTR-2′ may be disposed on the first electrode EL1′ defining the second pixel region PXA-G, and a sixth transport region HTR-3′ may be disposed on the first electrode EL1′ defining the third pixel region PXA-R.

The electron transport layer ETL′ may be disposed between the light emitting layer EML and the second electrode EL2′. That is, a first transport region ETR-1′ may be disposed on the first light emitting layer EML-B, a second transport region ETR-2′ may be disposed on the second light emitting layer EML-G, and a third transport region ETR-3′ may be disposed on the third light emitting layer EML-R.

Unlike the inverted light emitting devices ED-1, ED-2, and ED-3 illustrated in FIG. 5, FIG. 6 illustrates an embodiment including the light emitting devices ED-1′, ED-2′, and ED-3′ in which the hole transport layer HTL′ is disposed between the first electrode EL1′, which is an anode, and the light emitting layer EML, and the electron transport layer ETL′ is disposed between the second electrode EL2′, which is a cathode, and the light emitting layer EML.

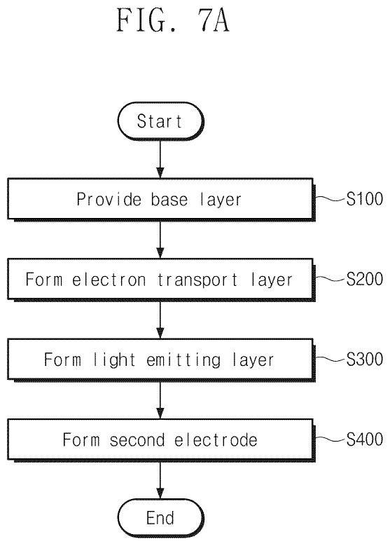

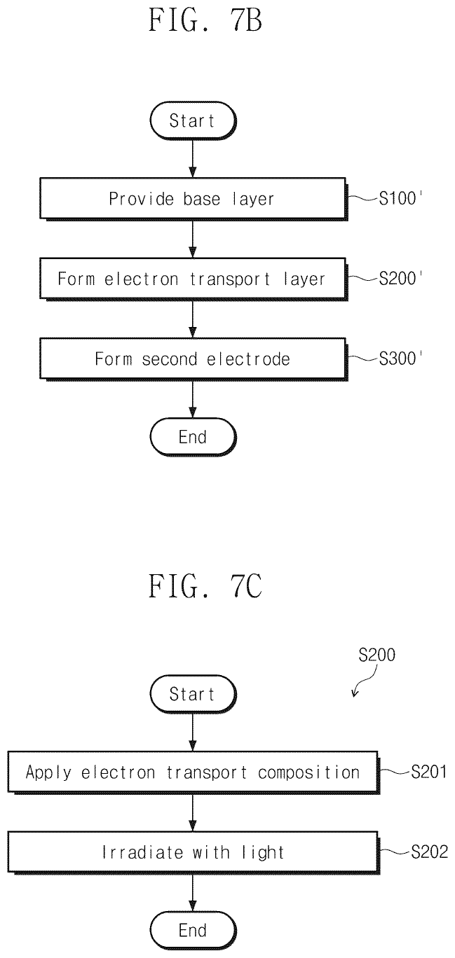

FIG. 7A and FIG. 7B are flowcharts showing a method for manufacturing a light emitting device according to an embodiment of the invention. FIG. 7C is a flowchart of subdivided steps of forming an electron transport layer according to an embodiment of the invention.

Referring to FIG. 7A, a method for manufacturing a light emitting device according to an embodiment may include providing a base layer S100, forming an electron transport layer on the base layer S200, forming a light emitting layer on the electron transport layer S300, and forming a second electrode on the light emitting layer S400. The present embodiment may correspond to a method for manufacturing the light emitting devices ED-1, ED-2, and ED-3 having a laminate structure of FIG. 5.

Referring to FIG. 5 together, in the providing of a base layer S100 of the present embodiment, the base layer may be a component which provides a reference surface on which an electron transport layer to be described later is formed. In an embodiment, the base layer includes first electrodes EL1 among components of light emitting devices ED-1, ED-2, and ED-3, and the reference surface may be an upper surface of the first electrodes EL1. At this time, each of the first electrodes EL1 may be a cathode.

In the forming of an electron transport layer S200 of the present embodiment, the electron transport layer ETL may be formed to be disposed on the first electrodes EL1.

Although not illustrated, after the forming of a light emitting layer S300 and before the forming of a second electrode S400, forming the hole transport layer HTL on the light emitting layer EML may be further included.

Referring to 7B, a method for manufacturing a light emitting device according to an embodiment may include providing a base layer S100′, forming an electron transport layer on the base layer S200′, and forming a second electrode on the electron transport layer S300′. The present embodiment may correspond to a method for manufacturing the light emitting devices ED-1′, ED-2′, and ED-3′ having a laminate structure of FIG. 6.

Referring to FIG. 6 together, in the providing of a base layer S100′ of the present embodiment, the base layer may be a component which provides a reference surface on which an electron transport layer to be described later is formed. In an embodiment, the base layer includes first electrodes EL1′ among components of the light emitting devices ED-1′, ED-2′, and ED-3′ and a light emitting layer EML disposed on the first electrodes EL1′, and the reference surface may be an upper surface of the light emitting layer EML. At this time, each of the first electrodes EL1′ may be an anode.

According to another embodiment, the base layer may further include a hole transport layer HTL′ disposed between the first electrodes EL1′ and the light emitting layer EML.

In the forming of an electron transport layer S200′ of the present embodiment, the electron transport layer ETL′ may be formed to be disposed on the light emitting layer EML.

Referring to FIG. 7C, the forming of an electron transport layer S200 according to an embodiment may include applying an electron transport material S201 and irradiating with light S202. The flowchart of FIG. 7C may be applied not only to the forming of an electron transport layer S200 of FIG. 7A but to the forming of an electron transport layer S200′ of FIG. 7B.

In the applying of an electron transport material S201, first to third preliminary transport regions ETR-I1, ETR-I2, and ETR-I3 (see FIG. 8D) are formed, and in the irradiating with light S202, the first to third preliminary transport regions ETR-I1, ETR-I2, and ETR-I3 are each irradiated with light to form an electron transport layer ETL (see FIG. 8I) including the first to third transport regions ETR-1, ETR-2, and ETR-3 (see FIG. 8I).

Hereinafter, referring to FIG. 8A to FIG. 8H, a method for manufacturing a light emitting device will be described in detail based on the light emitting devices ED-1, ED-2, and ED-3 of FIG. 5, which may be similarly applied to a method for manufacturing the light emitting devices ED-1′, ED-2′, and ED-3′ of FIG. 6.

FIG. 8A and FIG. 8B are cross-sectional views showing some of steps of a method for manufacturing a light emitting device according to an embodiment of the invention. FIG. 8C is a view schematically showing an electron transport composition according to an embodiment of the invention. FIG. 8D to FIG. 8G are cross-sectional views showing some of steps of a method for manufacturing a light emitting device according to an embodiment of the invention. FIG. 8H is a view showing steps of a reaction occurring in an electron transport material. FIG. 8I is a cross-sectional view showing some of steps of a method for manufacturing a light emitting device according to an embodiment of concept.

Referring to FIG. 8A, the method for manufacturing a light emitting device may include the providing of a base layer S100 (see FIG. 7A).

In the present embodiment, a base layer BL may include a first base substrate BS1, a circuit layer DP-CL disposed on the first base substrate BS1, first electrodes EL1 disposed on the circuit layer DP-CL, and a pixel definition film PDL disposed on the circuit layer DP-CL and having first to third pixel openings OH1, OH2, and OH3 defined thereon which expose at least a portion of a corresponding first electrode among the first electrodes EL1. In the present embodiment, the first electrodes EL1 may be a cathode.

On the base layer BL, the first to third pixel regions PXA-B, PXA-G, and PXA-R may be defined. The first to third pixel regions PXA-B, PXA-G, and PXA-R may be defined as regions in the first electrodes EL1 exposed from the pixel definition film PDL by the first to third pixel openings OH1, OH2, and OH3, respectively.

Referring to FIG. 8B to FIG. 8D, a method for manufacturing a light emitting device includes forming an electron transport layer S200 (see FIG. 7A), and the forming of an electron transport layer S200 (see FIG. 7A) may include applying an electron transport layer S201 (see FIG. 7C).

As illustrated in FIG. 8B and FIG. 8D, in the applying of an electron transport material S201 (see FIG. 7C), an electron transport composition ICP may be applied on the first electrodes EL1 exposed from the pixel definition film PDL. The applied electron transport composition ICP may form a preliminary electron transport layer ETL-I. The preliminary electron transport layer ETL-I may include first to third preliminary transport regions ETR-I1, ETR-I2, and ETR-I3.

The electron transport composition ICP may be applied on the first electrode EL1 defining the first pixel region PXA-B among the first electrodes EL1 to form the first preliminary transport region ETR-I1. The electron transport composition ICP may be applied on the first electrode EL1 defining the second pixel region PXA-G among the first electrodes EL1 to form the second preliminary transport region ETR-I2. The electron transport composition ICP may be applied on the first electrode EL1 defining the third pixel region PXA-R among the first electrodes EL1 to form the third preliminary transport region ETR-I3.

A method for applying the electron transport composition ICP is not particularly limited, and a method such as spin coating, casting, Langmuir-Blodgett (“LB”), inkjet printing, laser printing, laser induced thermal imaging (“LITI”), and the like may be used. FIG. 8B illustrates that the electron transport composition ICP is applied between the pixel definition film PDL through a nozzle NZ, but the embodiment of the invention is not limited thereto.

As illustrated in FIG. 8C, the electron transport composition ICP according to an embodiment may include the metal oxide MO and the photoacid generator PG. In the present embodiment, the first to third preliminary transport regions ETR-I1, ETR-I2, and ETR-I3 may be formed by the electron transport composition ICP having substantially the same mass ratio of the photoacid generator PG to the metal oxide MO. In the present disclosure, “substantially the same” means not only having the physically same numerical value but also having slightly different numerical values within an error range that may occur in a process.

According to an embodiment, the metal oxide MO may include an oxide of a metal including at least one of silicon, aluminum, zinc, indium, gallium, yttrium, germanium, scandium, titanium, tantalum, hafnium, zirconium, cerium, molybdenum, nickel, chromium, iron, niobium, tungsten, tin, or copper, or a mixture thereof, but is not limited thereto.

For example, the metal oxide MO may include a zinc oxide. The type of the zinc oxide is not particularly limited, but may be, for example, ZnO, ZnMgO, or a combination thereof, and Li, Y, or the like may be doped in addition to Mg. In addition, the metal oxide MO may include TiO₂, SiO₂, SnO₂, WO₃, Ta₂O₃, BaTiO₃, BaZrO₃, ZrO₂, HfO₂, Al₂O₃, Y₂O₃, ZrSiO₄, or the like in addition to the zinc oxide, but is not limited thereto.

In the present disclosure, the photoacid generator PG may mean a material which emits at least one acid by irradiation of light such as visible light, ultraviolet light, infrared light, or the like. In the present disclosure, an “acid” may mean a compound which provides hydrogen ions (H⁺).

According to an embodiment, the photoacid generator PG may be an ionic or non-ionic compound. Examples of the photoacid generator PG include, but are not limited to, compounds such as sulfonium-based, iodonium-based, phosphonium-based, diazonium-based, sulfonate-based, pyridinium-based, triazine-based, and imide-based compounds. The photoacid generator PG may be used alone or two or more thereof may be mixed and used. In addition, the photoacid generator PG may include generating an acid by applying energy such as heating other than light.

According to an embodiment, the electron transport composition ICP may further include a solvent SV. The solvent SV may be an organic solvent or an inorganic solvent such as water. The organic solvent may include an aprotic solvent or a protic solvent.

The aprotic solvent may include, for example, hexane, toluene, chloroform, dimethyl sulfoxide, octane, xylene, hexadecane, cyclohexylbenzene, triethylene glycol monobutyl ether or dimethyl formamide, decane, dodecane hexadecene, cyclohexylbenzene, tetrahydronaphthalene, ethylnaphthalene, ethylbiphenyl, isopropylnaphthalene, diisopropylnaphthalene, diisopropylbiphenyl, xylene, isopropylbenzene, pentylbenznene, diisopropylbenzene, decahydronaphthalene, phenylnaphthalene, cyclohexyldecahydronaphthalene, decylbenzene, dodecylbenzene, octylbenzene, cyclohexane, cyclopentane, cycloheptane, or the like, but is not limited thereto.

The protic solvent may be a compound capable of providing at least one proton. More specifically, the protic solvent may be a compound containing at least one dissociable proton. For example, the protic solvent may mean a protic liquid material or a protic polymer. The type of the protic solvent may include, for example, methanol, ethanol, propanol, isopropanol, ethylene glycol, propylene glycol, diethylene glycol, or the like, but is not limited thereto.

According to an embodiment, the electron transport composition ICP may further include a weak acid (not shown). Since the weak acid (not shown) is included, an acid may be slowly released from the photoacid generator PG, and the dispersion stability of the metal oxide MP may be improved. Accordingly, the preliminary electron transport layer ETL-I may be formed as a uniform thin film. For example, the weak acid (not shown) may have a pKa (acid dissociation constant) of approximately 4.75 or greater.

Referring to FIG. 8E to FIG. 8H, a method for manufacturing a light emitting device includes forming an electron transport layer S200 (see FIG. 7A), and the forming of an electron transport layer S200 (see FIG. 7A) may include irradiating a preliminary electron transport layer with light S202 (see FIG. 7C).

First, referring to FIG. 8E, the irradiating with light S202 (see FIG. 7C) may include irradiating the first preliminary transport region ETR-I1 with a first light LT1. In the irradiating with the first light LT1, a first mask MK1 may be disposed on the preliminary electron transport layer ETL-I (or the electron transport composition ICP (see FIG. 8B)). The first mask MK1 may define a first opening OP1 therein overlapping the first preliminary transport region ETR-I1 in a plan view. The first opening OP1 may be formed by penetrating from an upper surface of the first mask MK1 to a lower surface thereof.

The first light LT1 is irradiated from a first light irradiation device LU1, and the irradiated first light LT1 may pass through the first opening OP1 and be irradiated on the first preliminary transport region ETR-I1. The first light LT1 is irradiated on the first preliminary transport region ETR-I1 for a predetermined period of time, so that the first preliminary transport region ETR-I1 may be converted into the first transport region ETR-1.

Thereafter, referring to FIG. 8F, the irradiating with light S202 (see FIG. 7C) may include irradiating the second preliminary transport region ETR-I2 with a second light LT2. In the irradiating with the second light LT2, a second mask MK2 may be disposed on the preliminary electron transport layer ETL-I (or the electron transport composition ICP (see FIG. 8B)). The second mask MK2 may define a second opening OP2 therein overlapping the second preliminary transport region ETR-I2 in a plan view. The second opening OP2 may be formed by penetrating from an upper surface of the second mask MK2 to a lower surface thereof.

The second light LT2 is irradiated from a second light irradiation device LU2, and the irradiated second light LT2 may pass through the second opening OP2 and be irradiated on the second preliminary transport region ETR-I2. The second light LT2 is irradiated on the second preliminary transport region ETR-I2 for a predetermined period of time, so that the second preliminary transport region ETR-I2 may be converted into the second transport region ETR-2.

According to the present embodiment, the amount of light per unit area irradiated on the second preliminary transport region ETR-I2 from the second light LT2 provided by the second light irradiation device LU2 (hereinafter, a second amount of light) may be different from the amount of light per unit area irradiated on the first preliminary transport region ETR-I1 from the first light LT1 provided by the first light irradiation device LU1 (hereinafter, a first amount of light). For example, the second amount of light may be less than the first amount of light.

In an embodiment, in order to control the second amount of light to be less than the first amount of light, the period of time during which the first light LT1 is irradiated and the period of time during which the second light LT2 is irradiated may be set to be the same, and the intensity of the second light LT2 may be set to be lower than the intensity of the first light LT1.

In addition, in another embodiment, in order to control the second amount of light to be less than the first amount of light, the intensity of the first light LT1 and the intensity of the second light LT2 may be set to be the same, and the period of time during which the second light LT2 is irradiated may be set to be shorter than the period of time during which the first light LT1 is irradiated.

In addition, in another embodiment, in order to control the second amount of light to be less than the first amount of light, the period of time during which the first light LT1 is irradiated, the period of time during which the second light LT2 is irradiated, the intensity of the first light LT1, and the intensity of the second light LT2 may all be controlled.

Thereafter, referring to FIG. 8G, the irradiating with light S202 (see FIG. 7C) may include irradiating the third preliminary transport region ETR-I3 with a third light LT3. Here, the first to third lights LT1 to LT3 may be ultraviolet lights. In the irradiating with the third light LT3, a third mask MK3 may be disposed on the preliminary electron transport layer ETL-I (or the electron transport composition ICP (see FIG. 8B)). The third mask MK3 may define a third opening OP3 therein overlapping the third preliminary transport region ETR-I3 in a plan view. The third opening OP3 may be formed by penetrating from an upper surface of the third mask MK3 to a lower surface thereof.

The third light LT3 is irradiated through a third light irradiation device LU3, and the irradiated third light LT3 may pass through the third opening OP3 and be irradiated on the third preliminary transport region ETR-I3. By being irradiated with the third light LT3 for a predetermined period of time, the third preliminary transport region ETR-I3 may be converted into the third transport region ETR-3.

According to the present embodiment, the amount of light per unit area irradiated on the third preliminary transport region ETR-I3 from the third light LT3 provided by the third light irradiation device LU3 (hereinafter, a third amount of light) may be different from the first amount of light and the second amount of light. For example, the third amount of light may be greater than the first amount of light and the second amount of light.

In an embodiment, in order to control the third amount of light to be greater than the first amount of light and the second amount of light, the period of time during which the first light LT1 is irradiated, the period of time during which the second light LT2 is irradiated, and the period of time during which the third light LT3 is irradiated may all be set to be the same, and the intensity of the third light LT3 may be set to be higher than the intensity of the first light LT1 and the intensity of the second light LT2.

In addition, in another embodiment, in order to control the third amount of light to be greater than the first amount of light and the second amount of light, the intensity of the first light LT1, the intensity of the second light LT2, and the intensity of the third light LT3 may all be set to be the same, and the period of time during which the third light LT3 is irradiated may be set to be longer than the period of time during which the first light LT1 is irradiated and the period of time during which the second light LT2 is irradiated.

In addition, in another embodiment, in order to control the third amount of light to be greater than the first amount of light and the second amount of light, the period of time during which each of the first to third lights LT1, LT2, and LT3 is irradiated and the intensity of each of the first to third lights LT1, LT2, and LT3 may all be controlled.

During the processes of FIG. 8E to FIG. 8G, by the irradiated first to third lights LT1, LT2, and LT3, the photoacid generator PG in the preliminary electron transport layer ETL-I including the first to third preliminary transport regions ETR-I1, ETR-I2, and ETR-I3 reacts, so that the electron transport layer ETL (see FIG. 8I) including the first to third transport regions ETR-1, ETR-2, and ETR-3 (see FIG. 8I) may be formed.

FIG. 8H shows, in the irradiating with light S202 (see FIG. 7C), reaction steps occurring in the electron transport composition ICP. Referring to FIG. 8H together with FIG. 5 and FIG. 8B to FIG. 8G, the surface of the metal oxide MO may be modified through hydrogen ions (H⁺) formed by decomposition of the photoacid generator PG in the electron transport composition ICP according to an embodiment.

A portion of the photoacid generator PG in the electron transport composition ICP may be decomposed by irradiated light and form an acid. Accordingly, the hydrogen ions (H⁺) may be adsorbed on the surface of the metal oxide MO, or the hydrogen ions (H⁺) may react with an acetate group adsorbed on the surface of the metal oxide MO, so that the acetate group may be removed from the metal oxide MO.

The metal oxide MO whose surface is modified by the acid decomposed from the photoacid generator PG may provide light emitting devices ED-1, ED-2, and ED-3 with improved electron mobility properties. As the number of the hydrogen ions (H⁺) adsorbed to the metal oxide MO increases, a Fermi level is moved closer to a conduction band (“CB”), so the energy difference between the Fermi level and the conduction band may be reduced. Accordingly, as the number of electrons of the metal oxide MO acting as a donor increases, an n-doping effect may be derived.

In addition, in general, when an acetate group is adsorbed to the metal oxide MO, a Fermi level is moved closer to a valence band (“VB”), so the energy difference between the Fermi level and the valence band may be reduced, and a p-doping effect may be derived. At this time, as the acetate group is removed from the metal oxide MO, the Fermi level is moved closer to the conduction band again, so that the p-doping effect may be reduced.

Accordingly, the current density of the light emitting devices ED-1, ED-2, and ED-3 increases, so that the luminescence efficiency and lifespan properties of the light emitting devices ED-1, ED-2, and ED-3 may be improved. At this time, according to the number of hydrogen ions (H⁺) to be adsorbed, that is, according to the concentration of hydrogen ions (H⁺) decomposed from the photoacid generator PG, the level at which the Fermi level is moved is controlled to control the degree of n-doping.

When forming an electron transport region to which a metal oxide is applied in a typical light emitting device, in order to improve luminescence efficiency and lifespan properties, a positive aging method has been applied in which a resin layer capable of supplying an acid on the electron transport region is introduced. However, since the method requires the addition of a series of processes for resin application, there is a problem in that the process efficiency is reduced due to an increase in process time and manufacturing costs. In addition, when the method is applied to a front luminous structure, there may be a problem in that a haze phenomenon caused by the resin layer occurs, so that transmittance is lowered.

On the other hand, according to the invention, by introducing the photoacid generator PG directly to the electron transport composition ICP, the manufacturing costs and process time may be reduced, so that the reliability and productivity of the display device DD (see FIG. 1) may be improved, and also, since the haze phenomenon caused by the resin is suppressed, the invention may be applied to both front and rear luminous structures.

At this time, according to a comparative example, the first to third preliminary transport regions ETR-I1, ETR-I2, and ETR-I3 are formed with the electron transport composition ICP having substantially the same mass ratio of the metal oxide MO to the photoacid generator PG, and substantially the same amount of light per unit area may be irradiated on the first to third preliminary transport regions ETR-I1, ETR-I2, and ETR-I3. At this time, the amount of acid decomposed from the photoacid generator PG may be substantially the same in the first to third transport regions ETR-1, ETR-2, and ETR-3.

However, the amount of electrons and holes required in forming excitons in the light emitting layer EML to emit light in a predetermined wavelength range may vary depending on the first to third light emitting devices ED-1, ED-2, and ED-3. In addition, as electrons and holes are provided in a similar amount to each other by a required amount, the efficiency of a light emitting device may be increased. Accordingly, according to a comparative example, the amount of electrons required in some light emitting devices among the first, second, and third light emitting devices ED-1, ED2, and ED-3 may not be satisfied. Alternatively, by generating electrons in an amount exceeding an amount required in some light emitting devices, the difference in the amount of holes generated may be large. Accordingly, the efficiency of some light emitting devices may be reduced.

However, according to the present embodiment, by differently setting the amount of light per unit area irradiated on each of the first to third preliminary transport regions ETR-I1, ETR-I2, and ETR-I3, the amount of acid decomposed from the photoacid generator PG in the first to third transport regions ETR-1, ETR-2, and ETR-3 may be controlled.

In the present embodiment, each of the first to third transport regions ETR-1, ETR-2, and ETR-3 may include the metal oxide MO, an acid decomposed from a portion of the photoacid generator PG, and the residual photoacid generator PG-R not decomposed, and the amount of acid decomposed from the photoacid generator PG in the first transport region ETR-1 (first decomposition amount), the amount of acid decomposed from the photoacid generator PG in the second transport region ETR-2 (second decomposition amount), and the amount of acid decomposed from the photoacid generator PG in the third transport region ETR-3 (third decomposition amount) may be different from each other.

For example, the amount of electrons required for emitting the first color light in the first light emitting layer EML-B may be greater than the amount of electrons required for emitting the second color light in the second light emitting layer EML-G. At this time, if the first amount of light irradiated on the first preliminary transport region ETR-I1 in the step of irradiating the first preliminary transport region ETR-I1 with the first light LT1 is greater than the second amount of light irradiated on the second preliminary transport region ETR-I2 in the step of irradiating the second preliminary transport region ETR-I2 with the second light LT2, the first decomposition amount for the photoacid generator PG in the first transport region ETR-1 may be greater than the second decomposition amount for the photoacid generator PG in the second transport region ETR-2. Through the above, the degree of n-doping in the first transport region ETR-1 may be greater than the degree of n-doping in the second transport region ETR-2, and it is possible to provide an amount of electrons required in both the first and second light emitting devices ED-1 and ED-2. Accordingly, by improving both the efficiency of each of the first and second light emitting devices ED-1 and ED-2 and the lifespan of the first and second light emitting devices ED-1 and ED-2, the reliability of each of the first and second light emitting devices ED-1 and ED-2 may be improved.

Through the above, the amount of acid decomposed from the photoacid generator PG in each of the first to third transport regions ETR-1, ETR-2, and ETR-3 may be set to match the amount of electrons required for emitting light of a predetermined color in the light emitting layer EML.

According to another embodiment of the invention, the amount of light per unit area irradiated on each of the first to third preliminary transport regions ETR-I1, ETR-I2, and ETR-I3 may be controlled in the irradiating with light S202 (see FIG. 7C), and at the same time, the mass ratio of the photoacid generator PG to the metal oxide MO applied on each of the first to third preliminary transport regions ETR-I1, ETR-I2, and ETR-I3 may be controlled in the applying of an electron transport material S201 (see FIG. 7C).

Referring to FIG. 8I, after the forming of an electron transport layer S200 (see FIG. 7A), the method for manufacturing a light emitting device according to an embodiment may include the forming of a light emitting layer S300 (see FIG. 3A), the forming of a hole transport layer, and the forming of a second electrode S400 (see FIG. 7A). FIG. 8I exemplarily illustrates the forming of a hole transport layer is further included after the forming of a light emitting layer S300 (see FIG. 7A) and before the forming of a second electrode S400 (see FIG. 7A).

In the forming of a light emitting layer S300 (see FIG. 7A), the light emitting layer EML may be formed on the electron transport layer ETL. The light emitting layer EML may include the first to third light emitting layers EML-B, EML-G, and EML-R. The first light emitting layer EML-B corresponds to the first pixel region PXA-B, and may be formed on the first transport region ETR-1. The second light emitting layer EML-G corresponds to the second pixel region PXA-G, and may be formed on the second transport region ETR-2. The third light emitting layer EML-R corresponds to the third pixel region PXA-R, and may be formed on the third transport region ETR-3.

In the forming of a hole transport layer, the hole transport layer HTL may be formed on the light emitting layer EML. The hole transport layer HTL may include the fourth to sixth transport regions HTR-1, HTR-2, and HTR-3. The fourth transport region HTR-1 corresponds to the first pixel region PXA-B, and may be disposed on the first light emitting layer EML-B. The fifth transport region HTR-2 corresponds to the second pixel region PXA-G, and may be formed on the second light emitting layer EML-G. The sixth transport region HTR-3 corresponds to the third pixel region PXA-R, and may be disposed on the third light emitting layer EML-R. According to another embodiment of the invention, the forming of a hole transport layer may be omitted.

In the forming of a second electrode S400 (see FIG. 7A), the second electrode EL2 may be formed on the hole transport layer HTL. The second electrode EL2 may be formed as a common layer so as to correspond to all of the first to third pixel regions PXA-B, PXA-G, and PXA-R. In the present embodiment, the second electrode EL2 may be an anode.

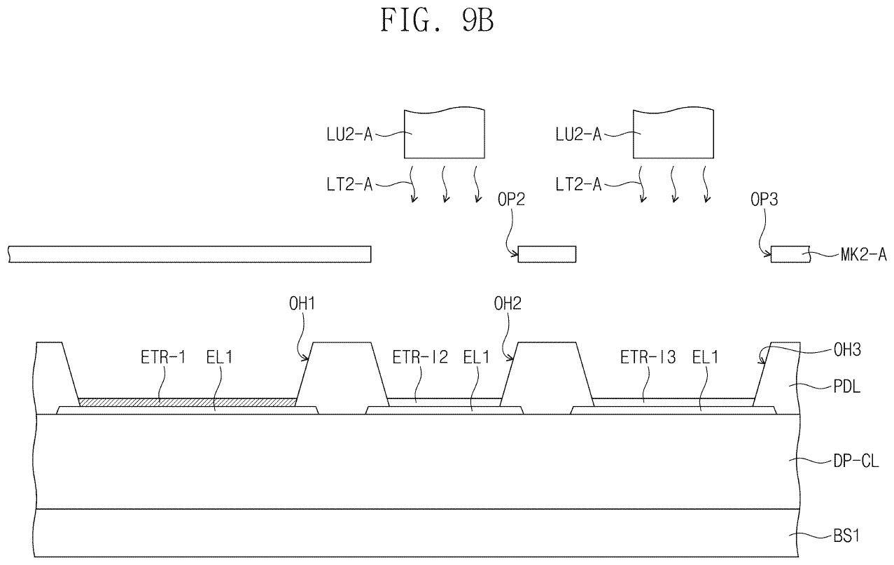

FIG. 9A and FIG. 9B are cross-sectional views showing some of steps of a method for manufacturing a light emitting device according to another embodiment of the invention. FIG. 9A and FIG. 9B illustrate the irradiating with light S202 (see FIG. 7C) in the forming of an electron transport layer S200 (see FIG. 7A). In describing the method for manufacturing a light emitting device of an embodiment with reference to FIG. 9A and FIG. 9B, the same/similar reference numerals are used for the same/similar components as those described with reference to FIG. 1 to FIG. 8I, and redundant descriptions thereof are omitted.

First, as illustrated in FIG. 9A, in the irradiating with light S202 (see FIG. 7C), a first mask MK1-A may be disposed on the preliminary electron transport layer ETL-I. The first mask MK1-A may define a first opening OP1 therein overlapping the first preliminary transport region ETR-I1 in a plan view.

A first light LT1-A may be irradiated through a first light irradiation device LU1-A. The irradiated first light LT1-A may pass through the first opening OP1 and be irradiated on the first preliminary transport region ETR-I1. The first light LT1-A is irradiated on the first preliminary transport region ETR-I1 for a predetermined period of time, so that the first preliminary transport region ETR-I1 may be converted into the first transport region ETR-1.

Thereafter, as illustrated in FIG. 9B, a second mask MK2-A may be disposed on the preliminary electron transport layer ETL-I. The second mask MK2-A may define a second opening OP2 therein overlapping the second preliminary transport region ETR-I2 and a third opening OP3 therein overlapping the third preliminary transport region ETR-I3 in a plan view.

A second light LT2-A may be irradiated from a second light irradiation device LU2-A. The irradiated second light LT2-A may pass through the second opening OP2 and be irradiated on the second preliminary transport region ETR-I2, and may pass through the third opening OP3 and be irradiated on the third preliminary transport region ETR-I3. The second light LT2-A is irradiated on each of the second and third preliminary transport regions ETR-I2 and ETR-I3 for a predetermined period of time, so that the second and third preliminary transport regions ETR-I2 and ETR-I3 may be converted into the second and third transport regions ETR-2 and ETR-3, respectively (see FIG. 5).

According to the present embodiment, the amount of light per unit area irradiated on each of the second and third preliminary transport regions ETR-I2 and ETR-I3 from the second light LT2-A provided by the second light irradiation device LU2-A (hereinafter, a 2-1 amount of light) may be different from the amount of light per unit area irradiated on the first preliminary transport region ETR-I1 from the first light LT1-A provided by the first light irradiation device LU1-A (hereinafter, a 1-1 amount of light).

The 1-1 amount of light and the 2-1 amount of light may be set by controlling the intensity of the first light LT1-A and the intensity of the second light LT2-A or by controlling the period of time during which the first light LT1-A is irradiated and the period of time during which the second light LT2-A is irradiated.

According to the present embodiment, through one mask MK1-A, two transport regions among the first to third preliminary transport regions ETR-I1, ETR-I2, and ETR-I3 may be simultaneously irradiated with light. When the amount of an acid required to provide an optimal amount of electrons is similar, by simultaneously irradiating light using the same mask, a process may be further simplified.

FIG. 9A and FIG. 9B exemplarily illustrate that the second and third preliminary transport regions ETR-I2 and ETR-I3 are simultaneously irradiated with light, but the type of preliminary transport regions simultaneously irradiated is not limited thereto.

Hereinafter, with reference to Examples and Comparative Examples through the results of Table 1, an effect of improving the efficiency and lifespan of light emitting devices manufactured according to an embodiment of the invention will be described in detail. In addition, Examples shown below are for illustrative purposes only to facilitate the understanding of the invention, and thus, the scope of the invention is not limited thereto.

TABLE 1

| | | Efficiency (a.u.) | | | Lifespan (a.u.) | | |
|---|---|---|---|---|---|---|---|
| | | B | G | R | B | G | R |
| Example 1 | UV exposure | 1.00 | 1.00 | 1.00 | 1.00 | 1.00 | 1.00 |
| | 3/10/12 mJ | | | | | | |
| Example 2 | UV exposure | 1.00 | 1.00 | 0.79 | 1.00 | 1.00 | 0.64 |
| | 3/10/10 mJ | | | | | | |
| Comparative | UV exposure | 0.42 | 0.86 | 1.00 | 0.24 | 0.68 | 1.00 |
| Example 1 | all 12 mJ | | | | | | |
| Comparative | UV exposure | 0.56 | 1.00 | 0.79 | 0.41 | 1.00 | 0.64 |
| Example 2 | all 10 mJ | | | | | | |
| Comparative | UV exposure | 1.00 | 0.63 | 0.51 | 1.00 | 0.52 | 0.32 |
| Example 3 | all 3 mJ | | | | | | |

Table 1 shows data values obtained by measuring the luminescence efficiency and lifespan of the first to third light emitting devices ED-1, ED-2, and ED-3 respectively including the first to third transport regions ETR-1, ETR-2, and ETR-3 of various embodiments manufactured by differently setting the amount of the first light irradiated on the first preliminary transport region ETR-I1, the amount of the second light irradiated on the second preliminary transport region ETR-I2, and the amount of the third light irradiated on the third preliminary transport region ETR-I3. At this time, the first to third transport regions ETR-1, ETR-2, and ETR-3 were manufactured to have the same area for the measurements, and the luminous efficiency was obtained by measuring the brightness per input power (cd/A), and the lifespan was obtained by measuring the time taken for the luminance of light provided from a light emitting device to be reduced to less than 90% based on the luminance of light initially provided.

Example 1 refers to the embodiment described above with reference to FIG. 8E to FIG. 8I of the invention in which the first to third amounts of light were all differently set, and Example 2 refers to the embodiment described above with reference to FIG. 9A and FIG. 9B of the invention in which the second and third amounts of light were set to be the same and the first amount of light was set to be different from the second and third amounts of light. On the other hand, Comparative Examples 1 to 3 refer to Comparative Examples in which the first to third amounts of light were all set to be the same. In Table 1 above, based on the luminescence efficiency and lifespan of a light emitting device measured in Example 1, the luminescence efficiency and lifespan of a light emitting device measured in Example 2 and Comparative Examples 1 to 3 are shown in a ratio value to those of Example 1.

Referring to the results of Comparative Example 1 to Comparative Example 3 in Table 1 above, it can be confirmed that, compared to a case in which the first amount of light is set to 3 millijoules (mJ), when the first amount of light is set to 10 mJ, the luminescence efficiency of the first light emitting device ED-1 is reduced by 0.56 times and the lifespan thereof is reduced by 0.41 times, and when the first amount of light is set to 12 mJ, the luminescence efficiency of the first light emitting device ED-1 is reduced by 0.42 times and the lifespan thereof is reduced by 0.24 times. That is, when the first amount of light is set to 3 mJ, the luminescence efficiency is the highest, so that the first light emitting device ED-1 having the longest lifespan may be provided.

Referring to the results of Comparative Example 1 to Comparative Example 3 in Table 1 above, it can be confirmed that, compared to a case in which the second amount of light is set to 10 mJ, when the second amount of light is set to 3 mJ, the luminescence efficiency of the second light emitting device ED-2 is reduced by 0.63 times and the lifespan thereof is reduced by 0.52 times, and when the second amount of light is set to 12 mJ, the luminescence efficiency of the second light emitting device ED-2 is reduced by 0.86 times and the lifespan thereof is reduced by 0.68 times. That is, when the second amount of light is set to 10 mJ, the luminescence efficiency is the highest, so that the second light emitting device ED-2 having the longest lifespan may be provided.

Referring to the results of Comparative Example 1 to Comparative Example 3 in Table 1 above, it can be confirmed that, compared to a case in which the third amount of light is set to 12 mJ, when the third amount of light is set to 3 mJ, the luminescence efficiency of the third light emitting device ED-3 is reduced by 0.51 times and the lifespan thereof is reduced by 0.32 times, and when the third amount of light is set to 10 mJ, the luminescence efficiency of the third light emitting device ED-3 is reduced by 0.79 times and the lifespan thereof is reduced by 0.64 times. That is, when the third amount of light is set to 12 mJ, the luminescence efficiency is the highest, so that the third light emitting device ED-3 having the longest lifespan may be provided.

That is, according to Comparative Examples 1 to 3, it can be confirmed that any one light emitting device among the first to third light emitting devices ED-1, ED-2, and ED-3 is provided with an amount of light suitable for providing an amount of required electrons, and thus, may have a high luminescence efficiency and a long lifespan, but the rest of the light emitting devices are not provided with an amount of required electrons, and thus, has a relatively low luminescence efficiency and a shot lifespan.

On the other hand, according to the invention, it can be confirmed that each of the first to third transport regions may be irradiated with a suitable amount of light as in Example 1, through which the luminescence efficiency and lifespan of all of the first to third light emitting devices ED-1, ED-2, and ED-3 may be maximized. That is, by suitably controlling the amount of acid decomposed from the photoacid generator PG in the first to third transport regions ETR-1, ETR-2, and ETR-3, an amount of electrons required in each of the first to third light devices ED-1, ED-2, ED-3 may be provided.

In addition, according to Example 2, the luminescence efficiency of the first light emitting device ED-1 may be degraded and the lifetime thereof may be shortened, but as long as the degree to which the luminescence efficiency is degraded and the degree to which the lifespan is shortened are acceptable in the operation of the display device DD (see FIG. 1), a cost reduction effect may be achieved through process simplification by simultaneously manufacturing the first and second transport regions ETR-1 and ETR-2.

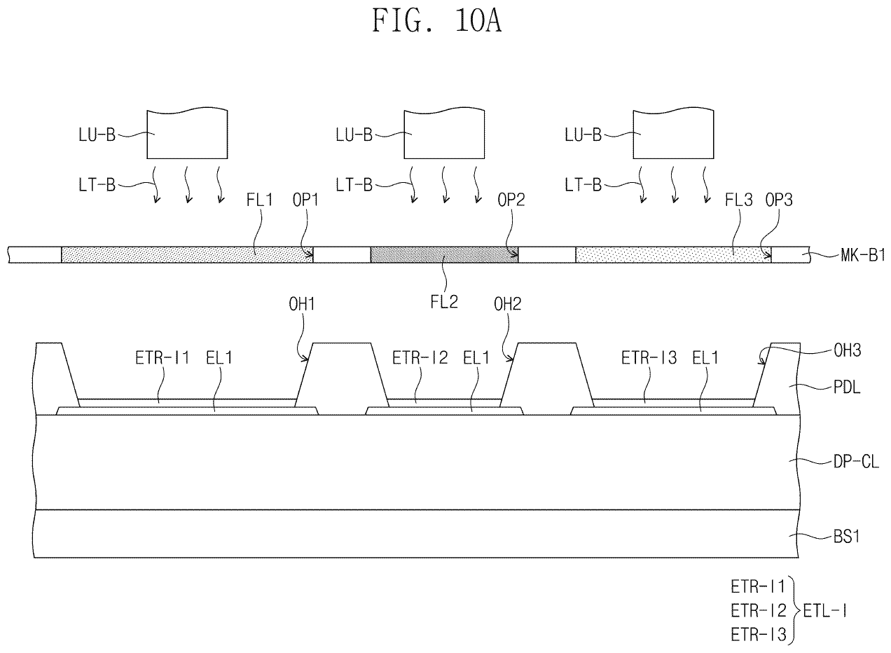

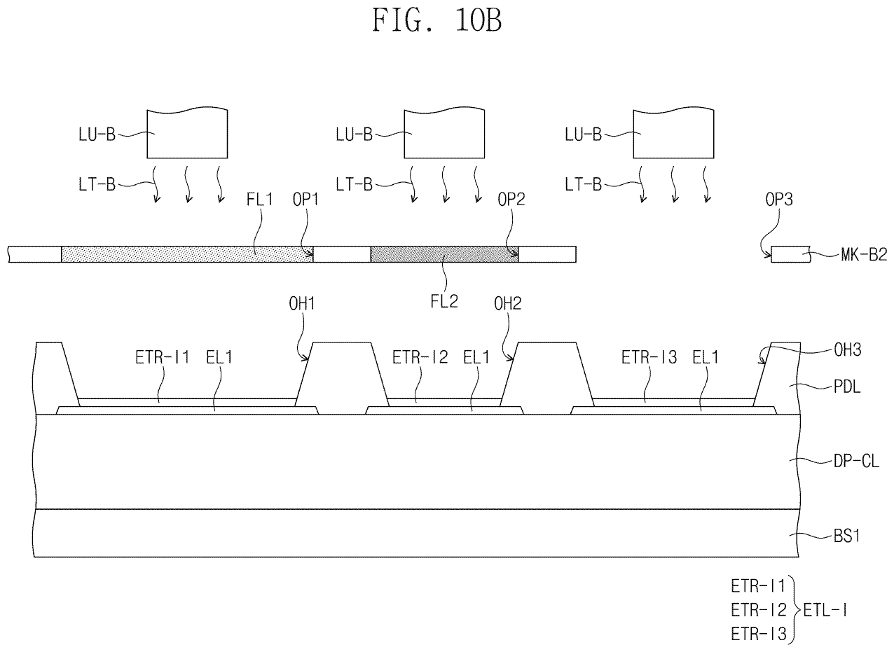

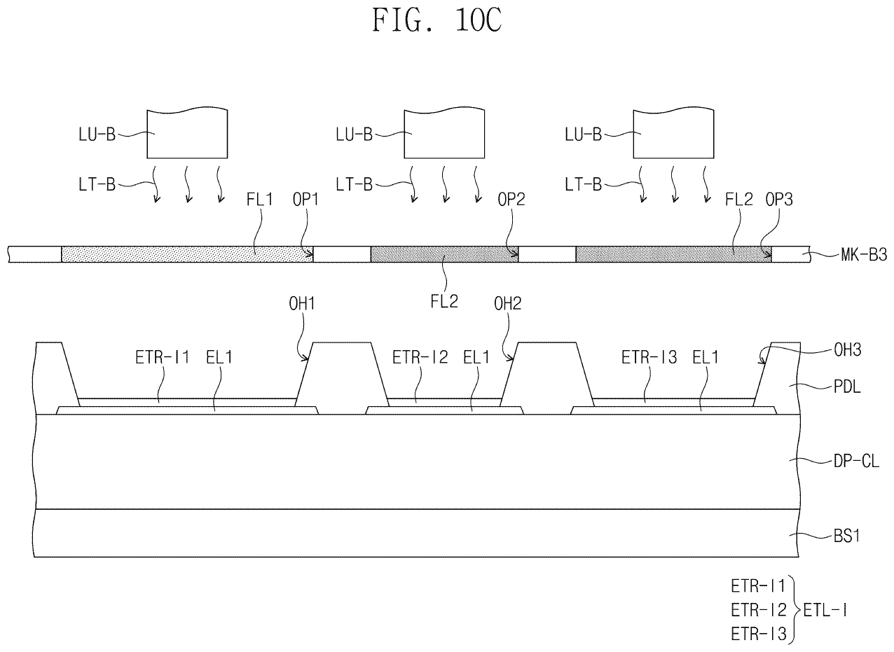

FIG. 10A to FIG. 10C are cross-sectional views showing some of steps of a method for manufacturing a light emitting device according to other embodiments of the invention. FIG. 10A to FIG. 10C each illustrate the irradiating with light S202 (see FIG. 7C) in the forming of an electron transport layer S200 (see FIG. 7A). In describing the method for manufacturing a light emitting device of an embodiment with reference to FIG. 10A and FIG. 10C, the same/similar reference numerals are used for the same/similar components as those described with reference to FIG. 1 to FIG. 8I, and redundant descriptions thereof are omitted.

Referring to FIG. 10A, in the irradiating with light S202 (see FIG. 7C), a common mask MS-B1 may be disposed on the preliminary electron transport layer ETL-I. The common mask MK-Bi may have the first opening OP1 overlapping the first preliminary transport region ETR-I1, the second opening OP2 overlapping the second preliminary transport region ETR-12, and the third opening OP3 overlapping the third preliminary transport region ETR-13 defined thereon in a plan view.

According to the present embodiment, a first light control film FL1 having a first light transmittance may be disposed in the first opening OP1, a second light control film FL2 having a second light transmittance may be disposed in the second opening OP2, and a third light control film FL3 having a third light transmittance may be disposed in the third opening OP3. For example, each of the first to third light control films FL1, FL2, and FL3 may be a photosensitive film. According to the present embodiment, the first to third light transmittances may be different from each other. For example, the second light transmittance may be higher than the first light transmittance and lower than the third light transmittance.

In the irradiating with light S202 (see FIG. 7C), the preliminary electron transport layer ETL-I may be irradiated with a common light LT-B through a common light irradiation device LU-B. The irradiated common light LT-B may pass through the first light control film FL1 and be irradiated on the first preliminary transport region ETR-I1, may pass through the second light control film FL2 and be irradiated on the second preliminary transport region ETR-I2, and may pass through the third light control film FL3 and be irradiated on the third preliminary transport region ETR-I3.

In the present embodiment, of the common light LT-B, the intensity of light passing through the first opening OP1, the intensity of light passing through the second opening OP2, and the intensity of light passing through the third opening OP3 may be different from each other. Accordingly, the intensity of light substantially irradiated on the first preliminary transport region ETR-I1, the intensity of light substantially irradiated on the second preliminary transport region ETR-I2, and the intensity of light substantially irradiated on the third preliminary transport region ETR-I3 may be different from each other. That is, the amount of light per unit area irradiated on the first to third preliminary transport regions ETR-I1, ETR-I2, and ETR-I3 may be different from each other.

For example, the amount of light per unit area irradiated on the second preliminary transport region ETR-I2 may be greater than the amount of light per unit area irradiated on the first preliminary transport region ETR-I1, and may be less than the amount of light per unit area irradiated on the third preliminary transport region ETR-I3.

Referring to FIG. 10B, on a common mask MK-B2 according to an embodiment, a first opening OP1, a second opening OP2, and a third opening OP3 may be defined. A first light control film FL1 having a first light transmittance may be disposed in the first opening OP1, and a second light control film FL2 having a second light transmittance may be disposed in the second opening OP2. Unlike the common mask MK-B1 illustrated in FIG. 10A, in the third opening OP3 of the common mask MK-B2 of the present embodiment, a separate light control film may not be disposed. Accordingly, the common light LT-B irradiated through the common light irradiation device LU-B may pass through the third opening OP3, and be directly irradiated on the third preliminary transport region ETR-I3.

FIG. 10B exemplarily illustrates that a separate light control film is not disposed in the third opening OP3, but the embodiment of the invention is not limited thereto, and a separate light control film may not be disposed in the first opening OP1 or the second opening OP2 in another embodiment.

Referring to FIG. 10C, on a common mask MK-B3 according to an embodiment, a first opening OP1, a second opening OP2, and a third opening OP3 may be defined in a common mask MK-B3. Unlike the common mask MK-B1 illustrated in FIG. 10A, in the first opening OP1 of the common mask MK-B3 of the present embodiment, a second light control film FL2 having a second light transmittance may be disposed in each of the second and third openings OP2 and OP3. That is, the light transmittance in the second opening OP2 and the light transmittance in the third opening OP3 may be substantially the same.

Accordingly, in the present embodiment, of the common light LT-B, the intensities of lights passing through the second and third openings OP2 and OP3 and being irradiated on the second and third preliminary transport regions ETR-I2 and ETR-I3, respectively, are substantially the same, and the amount of light per unit area irradiated on the second and third preliminary transport regions ETR-I2 and ETR-I3, respectively, may be substantially the same.

FIG. 10C exemplarily illustrates that light control films having the same light transmittance are disposed in the second and third openings OP2 and OP3, respectively, but the embodiment of the invention is not limited thereto, and light control films having the same light transmittance may be disposed in the first and second openings OP1 and OP2 or in the first and third openings OP1 and OP3, respectively, in another embodiment.

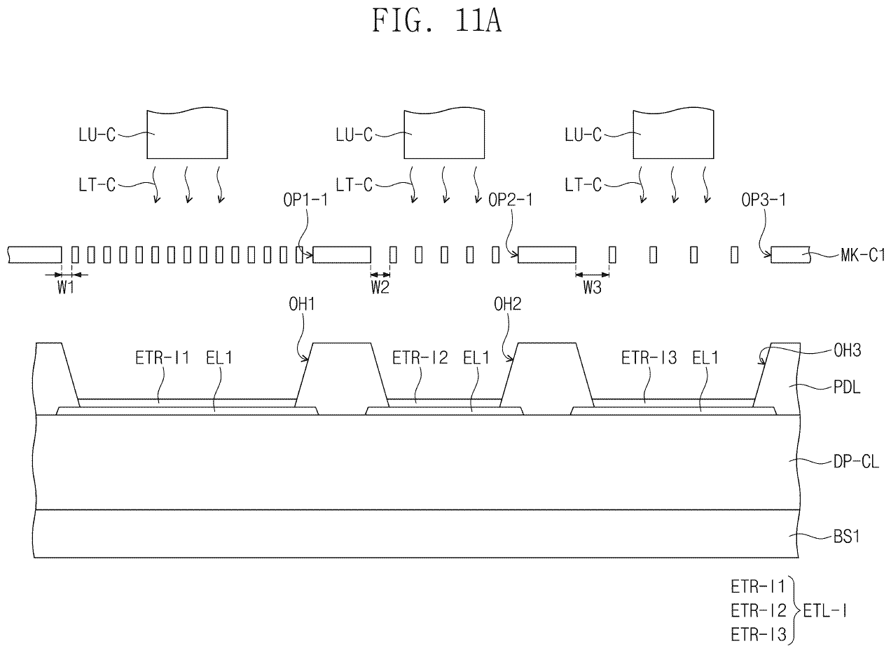

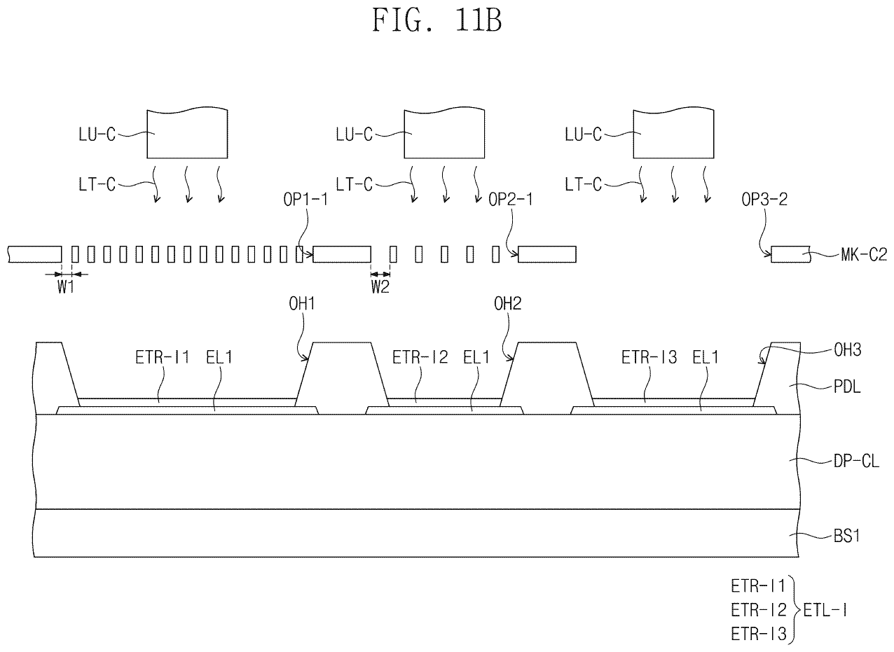

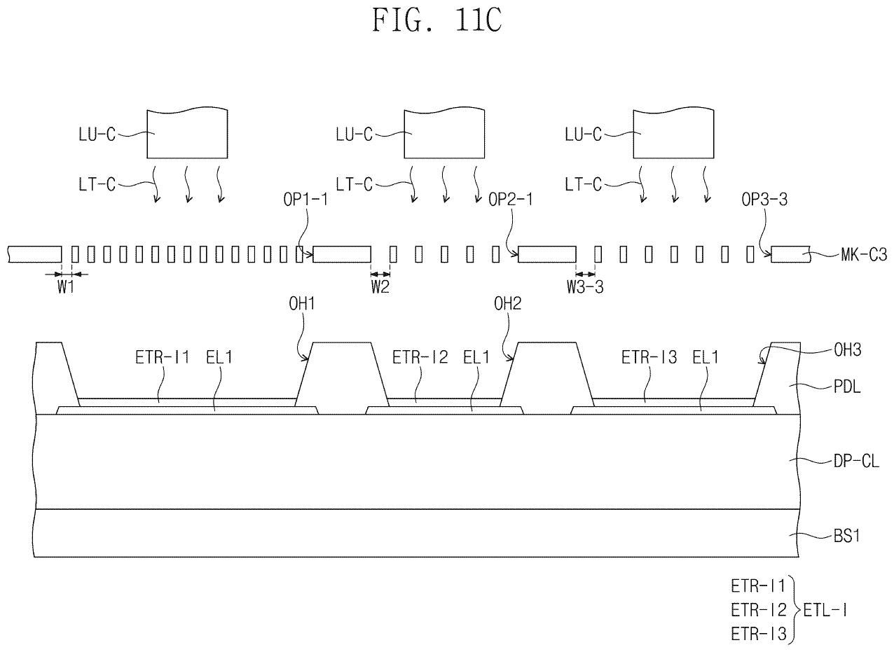

FIG. 11A to FIG. 1 IC are cross-sectional views showing some of steps of a method for manufacturing a light emitting device according to other embodiments of the invention. FIG. 11A to FIG. 11C each illustrate the irradiating with light S202 (see FIG. 7C) in the forming of an electron transport layer S200 (see FIG. 7A). In describing the method for manufacturing a light emitting device of an embodiment with reference to FIG. 11A and FIG. 11C, the same/similar reference numerals are used for the same/similar components as those described with reference to FIG. 1 to FIG. 8I, and redundant descriptions thereof are omitted.

Referring to FIG. 11A, in the irradiating with light S202 (see FIG. 7C), a common mask MK-C1 may be disposed on the preliminary electron transport layer ETL-I. In the common mask MK-C1, a plurality of first openings OP1-1 overlapping one first preliminary transport region ETR-I1, a plurality of second openings OP2-1 overlapping one second preliminary transport region ETR-I2, and a plurality of third openings OP3-1 overlapping one third preliminary transport region ETR-I3 in a plan view may be defined. Each of the first to third openings OP1-1, OP2-1, and OP3-1 may be provided in the form of a slit.

In the present embodiment, a width w1 (hereinafter, a first slit width) between the first openings OP1-1, a width w2 (hereinafter, a second slit width) between the second openings OP2-1, and a width w3 (hereinafter, a third slit width) between the third openings OP3-1 may be different from each other. For example, the second slit width w2 may be greater than the first slit width w1, and less than the third slit width w3.

In the irradiating with light S202 (see FIG. 7C), the preliminary electron transport layer ETL-I may be irradiated with a common light LT-C through a common light irradiation device LU-C. The irradiated common light LT-C may pass through the first openings OP1-1 and be irradiated on the first preliminary transport region ETR-I1, may pass through the second openings OP2-1 and be irradiated on the second preliminary transport region ETR-I2, and may pass through the third openings OP3-1 and be irradiated on the third preliminary transport region ETR-I3.

In the present embodiment, of the common light LT-C, the intensity of light passing through the first openings OP1-1, the intensity of light passing through the second openings OP2-1, and the intensity of light passing through the third openings OP3-1 may be different from each other. Accordingly, the intensity of light substantially irradiated on the first preliminary transport region ETR-I1, the intensity of light substantially irradiated on the second preliminary transport region ETR-I2, and the intensity of light substantially irradiated on the third preliminary transport region ETR-I3 may be different from each other. That is, the amount of light per unit area irradiated on the first to third preliminary transport regions ETR-I1, ETR-I2, and ETR-I3 may be different from each other.

For example, the amount of light per unit area irradiated on the second preliminary transport region ETR-I2 may be greater than the amount of light per unit area irradiated on the first preliminary transport region ETR-I1, and may be less than the amount of light per unit area irradiated on the third preliminary transport region ETR-I3.

Referring to FIG. 11B, unlike the common mask MK-C1 illustrated in FIG. 11A, in a common mask MK-C2 according to an embodiment, a plurality of first openings OP1-1 overlapping one first preliminary transport region ETR-I1, a plurality of second openings OP2-1 overlapping one second preliminary transport region ETR-I2, and one third opening OP3-2 overlapping one third preliminary transport region ETR-I3 in a plan view may be defined. Accordingly, in the present embodiment, the common light LT-C irradiated through the common light irradiation device LU-C may pass through the third opening OP3-2, and be directly irradiated on the third preliminary transport region ETR-I3.

Referring to FIG. 11C, in the common mask MK-C3 according to an embodiment, a plurality of first openings OP1-1 overlapping one first preliminary transport region ETR-I1, a plurality of second openings OP2-1 overlapping one second preliminary transport region ETR-I2, and a plurality of third openings OP3-3 overlapping one third preliminary transport region ETR-I3 in a plan view may be defined.

Unlike the embodiment illustrated in FIG. 11A, in the present embodiment, a second slit width w2 and a third slit width w3-3 may be substantially the same. A first slit width w1 may be less than each of the second and third slit widths w2 and w3-3. Accordingly, of the common light LT-C irradiated through the common light irradiation device LU-C, the transmittance of light passing through the second and third openings OP2-1 and OP3-3 may be substantially the same.

Accordingly, in the present embodiment, of the common light LT-C, the intensity of light passing through the second and third openings OP2 and OP3 and be irradiated on the second and third preliminary transport regions ETR-I2 and ETR-I3, respectively, are substantially the same, and the amount of light per unit area irradiated on the second and third preliminary transport regions ETR-I2 and ETR-I3, respectively, may be substantially the same.

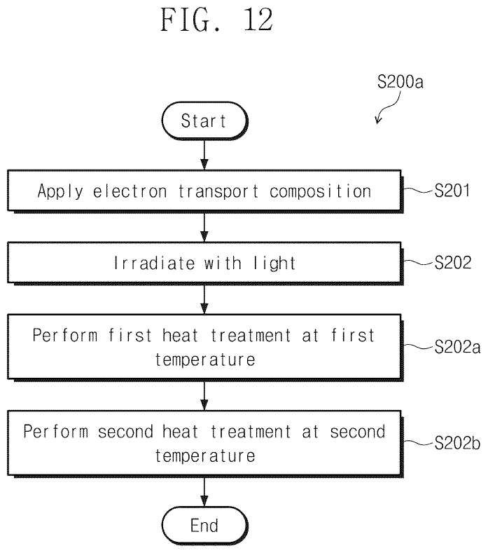

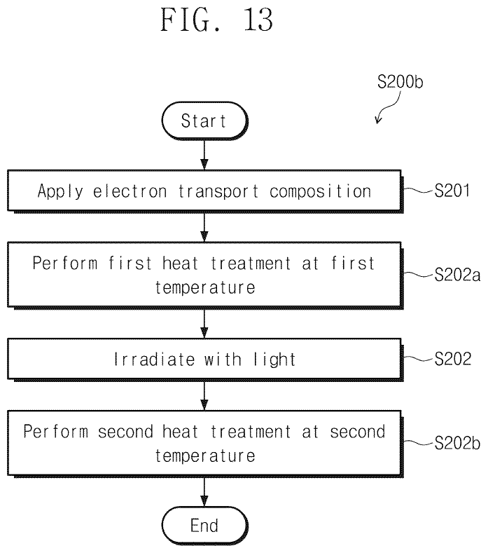

FIG. 12 and FIG. 13 are flowcharts showing a method for manufacturing a light emitting device according to other embodiments of the invention.

Referring to FIG. 12, forming an electron transport layer S200a according to an embodiment may further include, after the irradiating with light S202, performing first heat treatment at a first temperature S202a and performing second heat treatment at a second temperature S202b.

The performing of first heat treatment S202a may be performing heat treatment on first to third transport regions at the first temperature for a predetermined period of time. Since the forming of an electron transport layer S200a according to an embodiment includes the performing of first heat treatment S202a, an unnecessary remaining solvent in the first to third transport regions may be removed, and accordingly, the electron transport layer ETL (see FIG. 8I) may be formed as a uniform thin film.

In an embodiment, the first temperature is not particularly limited, but may be approximately 100° C. to approximately 150° C., preferably approximately 110° C. to approximately 145° C. However, the embodiment of the invention is not limited thereto. The heat treatment temperature and heat treatment duration in the performing of heat treatment at a first temperature S202a may be suitably selected depending on the type, amount, or the like of materials.

The performing of second heat treatment S202b may be performing heat treatment at the second temperature for a predetermined period of time. Through the performing of second heat treatment S202b, the degree of interaction between hydrogen ions (H⁺) formed from the photoacid generator PG (see FIG. 8H) and the metal oxide MO (see FIG. 8H) may be controlled.

In an embodiment, the second temperature may be a temperature lower than the above-described first temperature, and may be, for example, approximately 50° C. to approximately 95° C., preferably approximately 60° C. to approximately 85° C.

In an embodiment, the performing of second heat treatment S202b may mean a step of continuously exposing light of certain intensity having a predetermined wavelength to first to third transport regions to stabilize the optical properties of an electron transport layer. In addition, conditions such as the wavelength, intensity, and exposure duration of light in the performing of second heat treatment S202b may be suitably selected depending on the type of materials. The performing of second heat treatment S202b is a process for improving optical physical properties of an electron transport layer, which may further improve the light efficiency of light emitting devices. In some cases, the performing of second heat treatment S202b may be omitted.

Referring to FIG. 13, the forming of an electron transport layer S200b according to an embodiment may further include the performing of first heat treatment S202a at the first temperature after the applying of an electron transport material S201 and before the irradiating with light S202, and may further include the performing of second heat treatment at the second temperature after the irradiating of light S202.

Unlike FIG. 12, in the present embodiment of FIG. 13, the performing of first heat treatment S202a is performed before the irradiating with light S202, and thus, may be performing heat treatment on first to third preliminary transport regions at the first temperature for a predetermined period of time. That is, the performing of first heat treatment Example S202a may have a different process order depending on materials to be included in an electron transport material. In the present embodiment, the performing of second heat treatment S202b may be omitted in some cases.

According to the present invention, by forming an electron transport layer using an electron transport composition including a metal oxide and a photoacid generator, a light emitting device exhibiting improved luminescence efficiency and lifespan properties may be manufactured. In addition, by improving the luminescence efficiency of each of light emitting devices emitting light of different colors, a light emitting device with improved reliability may be manufactured.

Although the present invention has been described with reference to preferred embodiments of the present invention, it will be understood by those skilled in the art that various modifications and changes in form and details may be made therein without departing from the spirit and scope of the present invention as set forth in the following claims. Accordingly, the technical scope of the present invention is not intended to be limited to the contents set forth in the detailed description of the specification, but is intended to be defined by the appended claims.

What is claimed is:

1. A method for manufacturing a light emitting device, the method comprising:
providing a base layer on which first and second pixel regions configured to emit first and second color lights different from each other, respectively, are defined; and
forming, on the base layer, an electron transport layer including first and second transport regions overlapping the first and second pixel regions, respectively, wherein the forming of the electron transport layer includes:
applying an electron transport composition including a metal oxide and a photoacid generator on the first and second pixel regions such that first and second preliminary transport regions are formed; and
irradiating the first and second preliminary transport regions with light to form the first and second transport regions from the first and second preliminary transport regions, respectively,
wherein in the irradiating with the light, an amount of the light per unit area irradiated on the first preliminary transport region is different from an amount of the light per unit area irradiated on the second preliminary transport region.

2. The method of claim 1, wherein the irradiating with the light includes:
irradiating the first preliminary transport region with a first light; and
irradiating the second preliminary transport region with a second light,
wherein in the irradiating with the first light, a first mask is disposed on the electron transport composition and a first opening overlapping the first preliminary transport region is defined in the first mask,
wherein in the irradiating with the second light, a second mask is disposed on the electron transport composition and a second opening overlapping the second preliminary transport region is defined in the second mask.

3. The method of claim 2, wherein an intensity of the first light is different from an intensity of the second light.

4. The method of claim 2, wherein a period of time during which the first light is irradiated is different from a period of time during which the second light is irradiated.

5. The method of claim 2, wherein:
on the base layer, a third pixel region configured to emit a third color light different from the first and second color lights is further defined;
the applying of the electron transport composition further comprises applying the electron transport composition on the third pixel region to further form a third preliminary transport region; and
the irradiating with the light further comprises irradiating the third preliminary transport region with a third light using a third mask in which a third opening overlapping the third preliminary third region is defined such that a third transport region is formed.

6. The method of claim 5, wherein an intensity of the first light, an intensity of the second light, and an intensity of the third light are different from one another.

7. The method of claim 5, wherein a period of time during which the first light is irradiated, a period of time during which the second light is irradiated, and a period of time during which the third light is irradiated are different from one another.

8. The method of claim 2, wherein:
on the base layer, a third pixel region configured to emit a third color light different from the first and second color lights is further defined;
the applying of the electron transport composition further comprises applying the electron transport composition on the third pixel region to further form a third preliminary transport region; and
in the irradiating of the second preliminary transport region with the second light, a third opening overlapping the third preliminary transport region is further defined in the second mask, and the third preliminary transport region is irradiated with the second light.

9. The method of claim 1, wherein in the irradiating with the light, a common mask on which a first opening overlapping the first preliminary transport region and a second opening overlapping the second preliminary transport region are defined is used, and a transmittance of the light passing through the first opening is different from a transmittance of the light passing through the second opening.

10. The method of claim 9, wherein a first light control film having a first light transmittance is disposed in the first opening.

11. The method of claim 10, wherein a second light control film having a second light transmittance different from the first light transmittance is disposed in the second opening.

12. The method of claim 9, wherein the first opening is provided in plurality and in a slit form having a first slit width between two adjacent first openings of the plurality of first openings.

13. The method of claim 12, wherein the second opening is provided in plurality and in a slit form having a second slit width between two adjacent second openings of the plurality of second openings, and the second slit width is different from the first slit form.

14. The method of claim 9, wherein:
on the base layer, a third pixel region configured to emit a third color light different from the first and second color lights is further defined;
the applying of the electron transport composition further comprises applying the electron transport composition on the third pixel region to further form a third preliminary transport region; and
in the irradiating with the light, a third opening overlapping the third preliminary transport region is further defined in the common mask, and a transmittance of the light passing through the third opening is different from the transmittance of the light passing through the first opening and the transmittance of the light passing through the second opening.

15. The method of claim 9, wherein:
on the base layer, a third pixel region configured to emit a third color light different from the first and second color lights is further defined;
the applying of the electron transport composition further comprises applying the electron transport composition on the third pixel region to further form a third preliminary transport region; and
in the irradiating with the light, a third opening overlapping the third preliminary transport region is further defined in the common mask, and a transmittance of the light passing through the third opening is substantially the same as any one of the transmittance of the light passing through the first opening and the transmittance of the light passing through the second opening.

16. The method of claim 1, wherein in the irradiating with the light, a first decomposition amount of acid is decomposed from the photoacid generator in the first preliminary transport region, and a second decomposition amount of acid is decomposed from the photoacid generator in the second preliminary transport region, and the second decomposition amount is different from the first decomposition amount.

17. The method of claim 1, wherein:
the base layer comprises first electrodes corresponding to the first and second pixel regions, respectively, and
after the forming of the electron transport layer, the method further comprises:
on the electron transport layer, forming a light emitting layer including first and second light emitting layers corresponding to the first and second pixel regions, respectively; and
forming a second electrode on the light emitting layer.

18. The method of claim 1, wherein
the base layer comprises:
first electrodes corresponding to the first and second pixel regions, respectively; and
a light emitting layer disposed on the first electrodes, and including first and second light emitting layers corresponding to the first and second pixel regions, respectively, and
the method further comprises:
after the forming of the electron transport layer, forming a second electrode on the electron transport layer.

19. The method of claim 1, wherein the forming of the electron transport layer further comprises:
after the applying of the electron transport composition and before the irradiating with the light, performing heat treatment on the first and second preliminary transport regions.

20. The method of claim 1, wherein the forming of the electron transport layer further comprises;
after the irradiating with the light, performing heat treatment on the first and second transport regions.

21. The method of claim 1, wherein after the irradiating with the light, the forming of the electron transport layer further comprises:
performing first heat treatment on the first and second transport regions at a first temperature; and
after the performing of the first heat treatment, performing second heat treatment on the first and second transport regions at a second temperature different from the first temperature.

22. A method for manufacturing a light emitting device, the method comprising:
providing a base layer on which first and second pixel regions configured to emit first and second color lights different from each other, respectively, are defined; and
forming an electron transport layer including first and second transport regions overlapping the first and second pixel regions, respectively, on the base layer, wherein the forming of an electron transport layer includes:
applying an electron transport composition including a metal oxide and a photoacid generator on the first and second pixel regions such first and second preliminary transport regions are respectively formed; and
irradiating the first and second preliminary transport regions with light such the first and second transport regions are formed from the first and second preliminary transport regions, respectively,
wherein: mass ratios of the photoacid generator to the metal oxide of the first and second preliminary transport regions are substantially the same,
in the irradiating with the light, a first decomposition amount of acid is decomposed from the photoacid generator in the first preliminary transport region, and a second decomposition amount of acid is decomposed from the photoacid generator in the second preliminary transport region, and
the second decomposition amount is different from the first decomposition amount.
